(19) United States
(12) Patent Application Publication
(10) Pub. No.: US 2022/0144662 A1
(43) Pub. Date: May 12, 2022

(54) Method for Direct Synthesis of Nanomaterials by Heating of Bulk Sources

(71) Applicant: Northeastern University, Boston, MA (US)

(72) Inventors: Davoud HEJAZI, Malden, MA (US); Swastik KAR, Belmont, MA (US); Renda TAN, Malden, MA (US)

(21) Appl. No.: 17/523,861

(22) Filed: Nov. 10, 2021

Related U.S. Application Data
(60) Provisional application No. 63/111,824, filed on Nov. 10, 2020.
(60) Provisional application No. 63/179,172, filed on Apr. 23, 2021.

(51) Int. Cl. C01G 39/06

(52) U.S. Cl. CPC C01G 39/06; B82Y 30/00

(57) ABSTRACT

Methods for making of nanomaterials from a bulk source material involve heating the material in an inert atmosphere, whereby a material having at least one nanometer scale dimension is formed on a nearby substrate surface. The heated bulk source material forms a vapor phase which is deposited in the form of the nanomaterial on a growth surface of the substrate. The methods require no complex machinery or devices, unlike chemical vapor deposition, and can be tuned to provide different forms of nanomaterials, such as two-dimensional or other crystalline forms. The methods can be used to make two-dimensional semiconductor materials and semiconductor devices.

### CROSS-REFERENCE TO RELATED APPLICATIONS

This application claims priority to U.S. Provisional Application No. 63/111,824, filed 10 Nov. 2020, and to U.S. Provisional Application No. 63/179,172, filed 23 Apr. 2021. Both of the aforementioned provisional applications are incorporated by reference herein in their entirety.

### STATEMENT REGARDING FEDERALLY SPONSORED RESEARCH OR DEVELOPMENT

This invention was made with government support under Grant No. 1351424 awarded by the National Science Foundation. The government has certain rights in the invention.

### BACKGROUND

Nanomaterials can be created from a variety of bulk materials, such as carbon, metals, alloys, metal salts, and various inorganic crystals. Many nanomaterials take on surprisingly unique or useful catalytic, optical, magnetic, conducting, and other properties, and have the potential for use in power generation, optics, medicine, nano-machinery, chemical synthesis, and other fields.

Previous methods of synthesizing nanomaterials can be complicated and costly, involving complicated equipment and limiting widespread investigation and utilization of nanomaterials. Previous chemical methods include chemical vapor deposition (CVD), vacuum deposition and vaporization, gas condensation, precipitation, sol-gel fabrication, and electrodeposition. Previous mechanical methods include milling, sonication and liquid-phase exfoliation (LPE) of graphite, and exfoliation using adhesive tape to produce graphene from bulk graphite. While CVD can be a suitable chemical method for fabricating 2D nanomaterials, it uses precursor reactant chemicals and an inert carrier gas. The precursor reactant chemicals evaporate at high temperatures and travel as a vapor through a quartz tube into a furnace, where they react to create a nanomaterial on a substrate. Conventional CVD requires vacuum and controlled delivery of two or more precursors using an inert carrier gas with highly controlled flow rates, and a long tube so each precursor can be placed in different parts of the tube, where the temperature of each part of the tube needs to be controlled exactly. These requirements make CVD a difficult and unpredictable method, which demands large equipment and sophisticated control systems. Thus, there is a need for more efficient, simpler, and less costly methods for the synthesis of high-quality nanomaterials.

### SUMMARY

The present technology provides methods for directly synthesizing nanomaterials at a surface of a substrate by heating of a bulk source material (source) in an inert atmosphere in proximity to the surface. The synthesized nanomaterials can be 2D nanomaterials, which can be synthesized and directly deposited onto the surface of a substrate. The methods can eliminate the need for a flowing carrier gas, a gas flow controller, precursor reactants, and different temperature controllers for different parts of a long tube, oven, or furnace, which are required for performing CVD. The methods disclosed herein can yield the same quality or better 2D nanomaterials as, for example, chemical vapor deposition (CVD) or mechanical exfoliation, but are simpler and less costly. The methods disclosed herein can easily be scaled as needed for a variety of applications.

The present technology can be further summarized by the following list of features.

1. A method for making a nanomaterial, the method comprising the steps of:

(a) providing a bulk source material, a substrate, an inert gas, an oven, and optionally a sealable container;

(b) placing the bulk source material and the substrate into the oven or the sealable container, wherein a growth surface of the substrate is disposed adjacent to the bulk source material;

(c) filling the oven or the sealable container with the inert gas and sealing the oven or sealable container to provide an inert atmosphere inside the oven or sealable container; and

(d) heating the bulk source material and the substrate in the inert atmosphere in the oven or in the sealable container placed in the oven, whereby a portion of the bulk source material forms a vapor and is deposited as the nanomaterial on the growth surface of the substrate.

2. The method of feature 1, wherein the vapor is formed in step (d) by sublimation, evaporation, or boiling of the bulk source material.
3. The method of feature 1 or feature 2, wherein the growth surface does not contact the bulk source material during step (d), and wherein at least a portion of the nanomaterial deposited on the growth surface consists of one or more layers of a two-dimensional nanomaterial, each layer having a thickness of less than about 1 nm.
4. The method of feature 3, wherein the growth surface is separated from the bulk source material by a gap of from about 0.1 mm to about 3 cm.
5. The method of feature 1 or feature 2, wherein the growth surface contacts the bulk source material at one or more contact sites during step (d), and wherein at least a portion of the nanomaterial deposited on the growth surface consists of a two-dimensional nanomaterial at least partially surrounding the contact site and disposed in a wrinkled pattern on the growth surface.
6. The method of any of the preceding features, wherein the bulk source material comprises M_{A}X_{B}, wherein M is a transition metal or a transition metal cation, X is a chalcogen, A=1 or 2, and B=1, 2, or 3.
7. The method of feature 6, wherein M is selected from the group consisting of Ti, Zr, Hf, V, Nb, Ta, Mo, W, Tc, Re, Co, Ni, Rh, Ir, Rd, and Pt; wherein X is selected from the group consisting of S, Se, and Te; and wherein A=1 and B=2.
8. The method of any of the preceding features, wherein the bulk source material is provided in form of a powder.
9. The method of any of the preceding features, wherein the bulk source material comprises two or more different bulk source materials having different chemical compositions, and wherein the deposited nanomaterial is an alloy of the two or more different bulk source materials.
10. The method of any of the preceding features, wherein the deposited nanomaterial is a two-dimensional nanomaterial comprising a material selected from the group consisting of GaS, GaSe, InS, InSe, HfS₂, HfSe₂, HfTe₂, MoS₂, MoSe₂, MoTe₂, NbS₂, NbSe₂, NbTe₂, NiS₂, NiSe₂, NiTe₂, PdS₂, PdSe₂, PdTe₂, PtS₂, PtSe₂, PtTe₂, ReS₂, ReSe₂, ReTe₂, TaS₂, TaSe₂, TaTe₂, TiS₂, TiSe₂, TiTe₂, WS₂, WSe₂, WTe₂, ZrS₂, ZrSe₂, and ZrTe₂.
11. The method of any of the preceding features, wherein step (c) comprises purging the oven or sealable container with the inert gas and sealing the oven or the sealable container using one or more valves.
12. The method of any of the preceding features, wherein the inert atmosphere is maintained at a pressure in the range from about 0.1 atmosphere (about 76 Torr) to about 10 atmospheres (about 7600 Torr) during deposition of the nanomaterial in step (d).
13. The method of any of the preceding features, wherein the inert gas is sealed within the oven or container, without flow through the oven or container, during step (d).
14. The method of any of the preceding features, wherein step (d) comprises raising the temperature in the oven to a first temperature followed by raising the temperature in the oven to a second temperature, higher than the first temperature, and then holding the oven temperature at the second temperature for a period of time sufficient to deposit the nanomaterial on the growth surface.
15. The method of feature 14, wherein the temperature is raised to the first and second temperatures at a rate in the range from about 1° C./minute to about 300° C./minute.
16. The method of feature 14 or feature 15, wherein the period of time is from about 5 minutes to about 4 hours.
17. The method of any of features 14-16, wherein the first temperature is from about 500° C. to about 650° C. and the second temperature is from about 700° C. to about 900° C.
18. The method of any of the preceding features, further comprising:

(e) cooling the substrate and the nanomaterial to ambient temperature.

19. The method of feature 18, wherein the substrate and the nanomaterial are kept in the inert atmosphere until cooled to the ambient temperature.
20. The method of any of the preceding features, wherein the nanomaterial is deposited without chemical reaction of the bulk source material with another substance or the inert atmosphere.
21. The method of any of the preceding features, wherein the sealable container comprises a quartz tube.
22. The method of any of the preceding features, wherein the nanomaterial has an A-exciton line width from about 36 meV to about 40 meV.
23. The method of feature 1, wherein the substrate is heated in step (d) to a different temperature than the bulk source material.
24. The method of any of the preceding features, wherein the substrate comprises Si, SiO₂, or a combination thereof.
25. The method of any of the previous features, wherein the growth surface has a surface roughness less than about 1 nm RMS.
26. The method of any of the preceding features, further comprising including a dopant material with the bulk source material or in the inert atmosphere.
27. The method of any of the preceding features, further comprising doping the deposited nanomaterial by dry bulk contact or gas diffusion using a dopant material.
28. The method of feature 26 or feature 27, wherein the dopant material comprises Nb, Re, Fe, Re, V, N, Cs, Pb, I, CI, Au, NH₃, CH₃, benzyl viologen, oleylamine, triphenylphospine, polyethylenimine, pristine diketopyrrolopyrrole based polymer (PDPP3T), O2, N2, a rare earth element, a transition metal, a chalcogen, a semiconductor material, a magnetic material, or a combination thereof.
29. The method of any of the preceding features, wherein the method is performed as part of a manufacture of a semiconductor device.
30. A nanomaterial made by the method of any of the preceding features.
31. The nanomaterial of feature 30, wherein the unmodified nanomaterial has an A-exciton line width in the range from about 36 meV to about 40 meV.
32. A device comprising the nanomaterial of feature 30 or 31.
33. The device of feature 32, wherein the device is selected from the group consisting of a substrate including the nanomaterial upon a surface of the substrate, a force detector, a direct band-gap device, an n-type device, a p-type device, an am bipolar carrier transport device, a field effect transistor, a direct write junction, a random access memory (RAM) device, an oscillator, a chemical and/or gas sensor, a zero-energy motion and/or zero-energy sensor device, an indirect-to-direct band gap switching device, a photo-luminescence device, a photovoltaic device, an accelerometer, an optical or electromagnetic filter, a plane polarizer, a circularly polarized filter, a pressure sensor, an energy storage device, and a conductor or a superconductor.

As used herein, the term “2D nanomaterial” refers to a material having nanoscale thickness (i.e., less than 1000 nm, or from about 0.3 nm to about 999 nm in thickness, or less than 100 nm thickness in the Z dimension), while extending in the X and Y dimensions as far as desired (i.e., at least 100 nm, 1000 nm, 10 microns, 100 microns, 1000 microns, or more in the X and/or Y dimensions). The 2D nanomaterial can have one or more layers, which can be a single atom in thickness. For example, the method can produce a single layer of graphene having a thickness of 0.345 nm, or a single layer of 2D boron nitride having a thickness of 0.334 nm. The 2D nanomaterials can include layers of different compounds. By repeating the methods using different bulk source materials, layer upon layer of different materials can be synthesized in 2D nanomaterials.

As used herein, the term “nanostructure” or “nanomaterial” refers to a structure having at least one dimension on the nanoscale, i.e., from about atomic thickness of about 0.3 nm to about 999 nm. Nanostructures can include, but are not limited to, nanosheets, nanotubes, nanoparticles, nanospheres, nanowires, nanocubes, and combinations thereof.

As used herein, the term “microstructure” or “micromaterial” refers to a structure having at least one dimension on the microscale, that is, at least about 1 micrometer.

As used herein, “alkali metal salts” are metal salts in which the metal ions are alkali metal ions, or metals in Group I of the periodic table of the elements, such as lithium, sodium, potassium, rubidium, cesium, or francium. “Alkaline earth metal salts” are metal salts in which the metal ions are alkaline earth metal ions, or metals in Group II of the periodic table of the elements, such as beryllium, magnesium, calcium, strontium, barium, or radium.

In a metal salt according to the present technology, the anion may be any negatively charged chemical species. Metals in metal salts according to the present technology may include but are not limited to alkali metal salts, alkaline earth metal salts, transition metal salts, aluminum salts, or post-transition metal salts, and hydrates thereof.

As used herein, examples of “chalcogens” include oxygen, sulfur, selenium, tellurium, and polonium.

As used herein, “post-transition metal salts” are metal salts in which the metal ions are post-transition metal ions, such as gallium, indium, tin, thallium, lead, bismuth, or polonium.

As used herein, “transition metal salts” are metal salts in which the metal ions are transition metal ions, or metals in the d-block of the periodic table of the elements, including the lanthanide and actinide series, or a salt including an element whose atom has a partially filled d sub-shell or which can give rise to cations with an incomplete d sub-shell. Transition metal salts include, but are not limited to, salts of scandium, titanium, vanadium, chromium, manganese, iron, cobalt, nickel, copper, zinc, yttrium, zirconium, niobium, molybdenum, technetium, ruthenium, rhodium, palladium, silver, cadmium, lanthanum, cerium, praseodymium, neodymium, promethium, samarium, europium, gadolinium, terbium, dysprosium, holmium, erbium, thulium, ytterbium, lutetium, hafnium, tantalum, tungsten, rhenium, osmium, iridium, platinum, gold, mercury, actinium, thorium, protactinium, uranium, neptunium, plutonium, americium, curium, berkelium, californium, einsteinium, fermium, mendelevium, nobelium, and lawrencium.

As used herein, the term “about” refers to a range of within plus or minus 10%, 5%, 1%, or 0.5% of the stated value.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with the alternative expression “consisting of” or “consisting essentially of”.

### BRIEF DESCRIPTION OF THE DRAWINGS

FIG. 1A shows a side-view schematic representation of an apparatus and a process for direct synthesis of nanomaterials by heating of bulk sources. FIG. 1B shows a perspective-view schematic representation of an apparatus and a process for direct synthesis of nanomaterials by heating of bulk sources, along with (at top) depicting an example of 2D-MoS₂ (in the shape of triangles) directly synthesized from MoS₂ powder. At right of FIG. 1B is shown an A-exciton linewidth of 2D-MoS₂ made by the direct growth methods disclosed herein, and the linewidth is compared with that of mechanically exfoliated (ME) and hBN-Capped 2D-MoS₂, showing the high quality of the present direct growth technology. FIG. 1C shows a schematic depiction of a bulk source material 5 (source or source powder), a substrate 50 including a growth surface 55, and two possible growth mechanisms. In FIG. 1C, when the source powder is not in contact with the growth surface of the substrate (vertical arrows 80, left), 2D-MoS₂ grows in the form of flat triangles (top left, Flat Samples), whereas, at the same growth run, if the powder comes in contact with the growth surface of the substrate (angled arrows 85, right), 2D-MoS₂ is forced to grow in the form of wrinkled circlelike patterns around the contact sites (i.e., nucleation sites, “Strained Samples”, top right). The side view of a MoS₂ crystal is also depicted, which shows one atomic layer of its lattice is about three atoms thick (which includes a total thickness of about 0.65 nm).

FIGS. 2A-2B show light microscope images of 2D-MoS₂ synthesized as described in Example 1, by having the source powder (bulk source material) not in contact with the surface of the substrate. FIGS. 2C-2D show optical images of wrinkled circular 2D-MoS₂ samples that were grown as described in Example 1, by having the source powder in contact with the surface of the substrate.

FIG. 3A shows an atomic force microscopy (AFM) image of directly grown triangular samples on a Si/SiO₂ substrate; two chosen areas for AFM profiles are lines “1” and “2”. White dots in FIG. 3A are initial deposition regions where the materials started to grow. FIGS. 3B and 3C show cross-sectional line profiles of two chosen areas, which are shown by the lines “1” and “2” in FIG. 3A. FIG. 3D shows the AFM image of a wrinkled circular sample (e.g., image of FIG. 2C). FIGS. 3E and 3F show cross-sectional line profiles of the chosen areas of FIG. 3D, which are indicated by the lines 3, 4, 5, and 6. FIG. 3G is an AFM image of a different part of the wrinkled circular sample, and the inset at upper right shows an optical image taken from the same location where the AFM image is obtained (e.g., image of FIG. 2C). FIGS. 3H and 31 are cross-sectional line profiles of the chosen areas of FIG. 3G, which are shown by the lines 7 and 8. The insets in each of the AFM images (FIG. 3D and FIG. 3G) are the optical images taken from the same locations where AFM images were obtained (compare to FIG. 2C).

FIG. 4A shows normalized photoluminescence (PL) spectra of a typical directly grown triangular sample (DG-Triangular), a directly grown wrinkled circular sample (DG-Circular), and a vapor-phase chalcogenization-grown (VPC-grown) sample as a comparison. The inset figure shows the average A-exciton peak position over all of the same type samples and their standard deviations. FIG. 4B shows smoothed Raman spectra vs. wavenumber of the same three types of samples, normalized with respect to their respective Si peak that appears at 520 cm⁻¹. The inset shows average Δ=ω[A_{1g}]−ω[E_{2g}¹] over all of the same type samples, and their standard deviations. FIG. 4C shows magnified Raman spectra from FIG. 4B. In FIG. 4C, the detailed Raman modes of 2D-MoS₂ are shown, attributed to the various lattice vibrational modes of this material under a 488 nm excitation. In FIG. 4C, the DG-Circular, DG-Triangular, and VPC spectra are labeled.

FIG. 5A shows normalized PL versus photon energies of directly grown (DG) triangular (top), DG-circular (middle), and VPC-grown (bottom) samples, with the Lorentzian curves fitted to the exciton and trion, the sum of which gives rise to the cumulative fit that is in agreement with the underlying PL spectra. FIG. 5B shows a histogram of A-exciton line widths for samples fabricated by various techniques, the histograms stacked for comparison, and FIG. 5C shows a histogram of corresponding A⁻-trion widths, obtained from Lorentzian fits, of the 2D-MoS₂ samples fabricated by various techniques. All samples are either grown on Si/SiO₂ or transferred onto it.

FIG. 5D shows normalized PL versus photon energy of directly grown triangular samples with the Lorentzian curves fitted to the exciton and trion, the superposition of which gives rise to the cumulative fit, which is very well in agreement with the underlying PL spectra. FIG. 5E is a histogram of A-exciton line widths, and FIG. 5F is a histogram of corresponding A⁻-trion line widths, obtained from Voigt fits, of the 2D-MoS₂ directly grown triangles and mechanically exfoliated(ME)-h-BN-capped samples.

### DETAILED DESCRIPTION

The present technology provides methods for direct synthesis of nanomaterials on a surface of a substrate by heating of a bulk source material (source) in the proximity of the surface. A bulk source utilized in the present methods can be in any bulk form, such as a powder containing different particle sizes. A bulk source material in a solid, non-powder form also can be utilized. A bulk source material comprising various elements can be utilized. For example, the bulk source can be a metal salt, an alloy, a transition metal salt, or a material mixed with a dopant. If the surface of the substrate contacts the bulk source material, the form of the synthesized nanomaterials on the surface can be changed as described below.

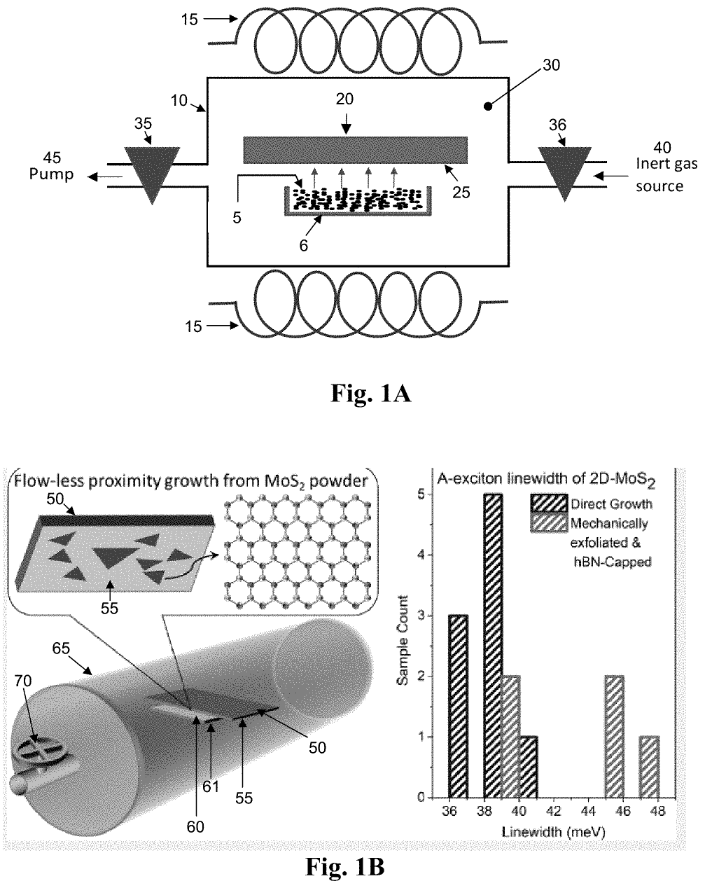

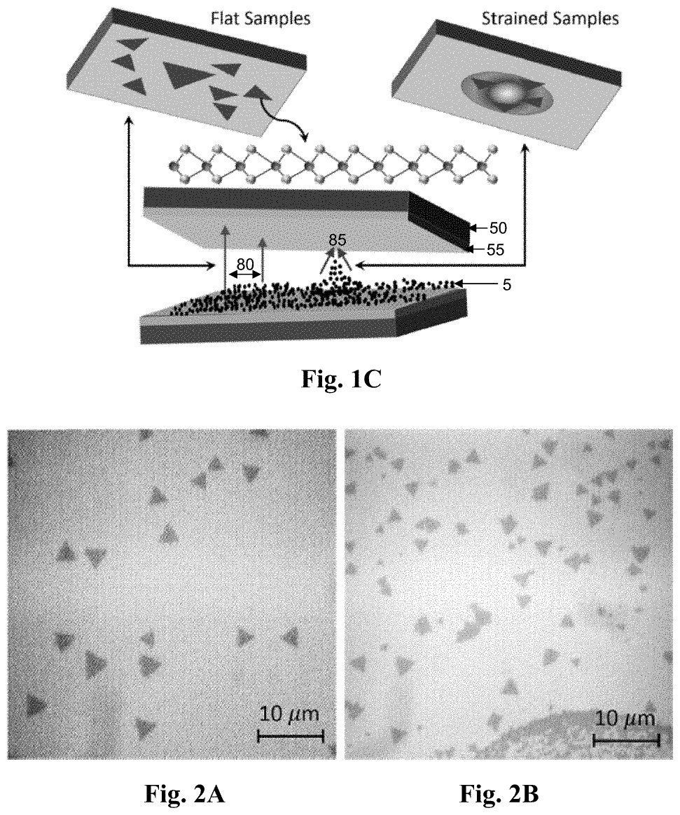

A method to directly synthesize nanomaterials can include heating a bulk source material in a closed (e.g., sealed) environment. Heating can be done by any known method, for example, in an oven, in a furnace, or in a container, using any suitable heat source. A bulk source material can be heated by placing the material inside of a quartz tube surrounded by heating elements. As illustrated in FIG. 1A, a bulk source material (or powder, source) 5 can be placed inside of a container 10 surrounded by one or more heating elements 15, with a substrate 20 (the intended target for deposition of a 2D nanomaterial layer) including a growth surface 25 near the bulk source 5. The bulk source material 5 can optionally be in or on any kind of holder, chip, or chip-crucible 6. At the inside 30 of the container 10 is an inert environment, such as an environment filled with an inert gas or a vacuum. The entire container 10 can be sealed, and optional valves 35, 36 can be utilized for purging and/or sealing. The entire container 10 can be a sealed container or tube that is placed into a larger oven (larger oven not shown). The valves 35, 36 can be utilized for variations of the methods wherein an inert gas flow is utilized.

After heating for a desired time at a desired temperature, the bulk source can enter the inert atmosphere, such as by sublimation, evaporation, or boiling within the heated container. Molecules and atoms derived from the bulk source can then collect, condense, or be deposited upon the substrate (or upon the surface 25 of the substrate) as a nanolayer, nanoparticles, a nanofilm, or patches or 2D crystals of the material. The substrate can optionally be temperature controlled and set at a different temperature, above or below the ambient temperature within the closed container, or the substrate can be at the same temperature as the rest of the closed container. Temperature gradients can be utilized including heating or cooling of one or more surfaces or the bulk source material. The one or more optional valves 35, 36 can be utilized to isolate the inside 30 of the container from an environment. An inert gas source 40 can be used. Vacuum pump 45 may be utilized to purge the inside of environmental oxygen or other reactive gases.

The methods disclosed herein can be carried out, either partially or fully, under an inert atmosphere or environment. An “inert atmosphere” refers to a gas or gaseous mixture that contains little or no oxygen or other undesired reactive gases, and includes inert or non-reactive gases or gases that have a high temperature threshold before they react, higher than the nanomaterial growth temperature. Preferably, the inert atmosphere does not chemically react with the bulk source material, or any doping material if present, at the growth temperature. An inert atmosphere can be an atmosphere under vacuum (below atmospheric pressure), at atmospheric pressure, or under elevated pressure (above atmospheric pressure). An inert atmosphere can be, but is not limited to, molecular nitrogen or an inert gas, such as argon, or mixtures thereof. Further examples of inert gases useful according to the present technology include, but are not limited to, gases comprising xenon (Xe), nitrogen (N), helium (He), radon (Rd), neon (Ne), argon (Ar), or combinations thereof. In the example of FIG. 1A, an inert gas source 40 introduces an inert gas, optionally with vacuum pump 45 (“Pump”, FIG. 1A) removing atmosphere.

In FIG. 1A, substrate 20 can be any material suitable for collection, crystallization, condensation, or deposition of the bulk source. The substrate can include growth surface 25 for deposition of the nanomaterial after bulk source material 5 is heated. For synthesis of 2D nanomaterials thereupon, growth surface 25 can be atomically smooth (having surface roughness features at the atomic scale or less), or can have surface roughness features at the nanometer scale. For example, the growth surface can have a surface roughness with features having about 1 nm RMS, with Rt in the range from about 10 nm to about 500 nm. Alternatively, optionally about Ra=10 nm at about Rt in the range from about 150 nm to about 300 nm, optionally less than about Ra=0.025 μm at Rt=0.3 μm (<RMS=1.1 μin., <“ISO grade N1”: ISO 1302:2002), or optionally the growth surface can have a roughness less than about Ra=0.05 μm at Rt=0.5 μm (<RMS=2.2 μm, <“ISO grade N2”). As used herein, “Ra” refers to the arithmetic average value (of absolute values) of a filtered roughness profile determined from deviations about a center line within an evaluation length, “Rt” refers to the total height range of the collected roughness data points, and “RMS” refers to root mean square roughness values (i.e., root mean square average of the profile height deviations from the mean line, recorded within the evaluation length). Visualization of surface roughness features and their quantification can be obtained use atomic force microscopy, for example.

The growth surface may have been subjected to a surface treatment, such as polishing, to provide a smooth growth surface. The growth surface also may include a crystal structure that facilitates growth of a structure of the nanomaterial deposited thereon (e.g., to provide an epitaxial growth surface). A nanomaterial previously deposited upon a growth surface may be utilized as a base upon which to deposit further nanomaterial layers, such that the previously deposited nanomaterial becomes a growth surface. For example, one layer of nanomaterial may be deposited, followed by a second layer of nanomaterial, followed by a third layer of nanomaterial, and so on, by repeating the method described herein until a desired number of layers are deposited. A multilayered nanomaterial can have the same or different materials deposited in each layer, as desired.

The substrate can be any desired material having suitable geometry or surface structure (such as being flat or having features at the atomic scale, nanometer scale, micron scale, or larger scale) and having any desired physical or chemical properties. The substrate can have a planar growth surface, or a growth surface with any other geometry, such as curved, concave, convex, stepped, or patterned by lithography. An example of a substrate is silicon having a coating of SiO₂. Another example is a nickel foil including a coating of graphene. The material selected for the substrate can be a semiconductor, a metal, a metal oxide, or a combination thereof. The substrate material can be electrically conductive or non-conductive. Optionally, the substrate material can be a ceramic, a salt, or a compound having an affinity for the bulk source material. The substrate can be referred to as a target. In FIG. 1A, substrate 20 is positioned above a powder bulk source 5. A substrate can be in any position relative to the bulk source within a heated environment. A portion of the substrate 20 (or the growth surface 25) can lack physical contact with the powder bulk source 5, which will cause a first method of nanomaterial growth discussed herein. A portion of the substrate 20 (or the growth surface 25) alternatively may contact the bulk source 5, which will cause a second method of nanomaterial growth discussed in detail herein.

A growth surface 25 of the substrate 20 can be in physical contact with a bulk source, or can be separated therefrom by a gap of less than about 0.5 mm, less than about 1.0 mm, less than about 5.0 mm, less than about 1 cm, or less than about 5 cm. Preferably, a gap between the substrate growth surface and the bulk source material can be separated by a gap from about 0.5 mm to about 3 cm.

The bulk source can collect on the substrate at any desired pressure. The pressure of the inert atmosphere can be range from about 0.1 atmosphere to about 10 atmospheres, including about 1 atmosphere. Pressures below atmospheric pressure can be obtained using a vacuum pump, and higher pressures can be obtained using a pressurized source of the inert gas, or can be obtained by heating the sealed container and allowing the pressure to build to a desired level. Pressure can be allowed to vary before, during, or after the nanomaterial deposition, as desired. Pressure can be selected based on selected heating temperature(s). That is, a higher pressure can be used with a lower temperature, or a lower pressure with a higher temperature, to achieve similar results. The practitioner will understand that pressure within the sealed container can affect the underlying vapor formation, i.e., by sublimation, evaporation, or boiling of the bulk source material.

After at least a portion of the bulk source collects upon the substrate in a collected form, annealing of the collected form can optionally be performed. Annealing can include holding the collected form at an annealing temperature, such as a temperature higher than the growth temperature or lower, for a suitable annealing time. Annealing can be performed in the same container or after transferring the collected nanomaterial to a different annealing area. Other post-synthetic treatments can be utilized to introduce defects or to introduce dopants.

Various nanomaterials or 2D nanomaterials can be synthesized by the methods disclosed herein. The 2D nanomaterials can be, for example, GaS, GaSe, InS, InSe, HfS₂, HfSe₂, HfTe₂, MoS₂, MoSe₂, MoTe₂, NbS₂, NbSe₂, NbTe₂, NiS₂, NiSe₂, NiTe₂, PdS₂, PdSe₂, PdTe₂, PtS₂, PtSe₂, PtTe₂, ReS₂, ReSe₂, ReTe₂, TaS₂, TaSe₂, TaTe₂, TiS₂, TiSe₂, TiTe₂, WS₂, WSe₂, WTe₂, ZrS₂, ZrSe₂, or ZrTe₂.

Without intending to be bound by theory or mechanism, the methods are believed to involve heating the bulk source material sufficiently until a sublimation occurs, such that a portion of the bulk source material enters the inert environment and diffuses to the growth surface, where the vapor condenses to form a solid phase nanomaterial deposited on the growth surface. The nanomaterial formed on the growth surface can be defect-free. As used herein, a “defect free” nanomaterial lacks tears, holes, or crystal defects, such as 2D crystal defects including vacancies. A “defect free” nanomaterial may include intentionally introduced defects. As used herein, a “defect free” nanomaterial can be demonstrated by, for example, an light microscopy, scanning electron microscopy, or atomic force microscopy image of a specific area or volume showing defect-free structure without contamination, artificial holes, voids, or tears. Various analytical tests also can be utilized to demonstrate a defect-free free condition of a nanomaterial. If a dopant is utilized in the nanomaterial, the dopant can be interspersed at regular intervals without interfering with a defect-free condition.

Nanomaterial growth generally requires a temperature much higher than ambient temperature in order to promote entry of the bulk source material into the inert atmosphere, preferably in atomic or molecular form. This can be accomplished by heating the sealed container by any desired method, such as placing it into an oven or furnace, or by placing the substrate and bulk source material into an oven or furnace directly, without use of a sealed container. The growth surface, substrate, bulk source material, and the inert atmosphere are preferably all heated to the same temperature, or they may be heated to different temperatures. Growth of the nanomaterial can be carried out at one, two, three, four, five or more different temperatures, using ramps or jumps between different temperatures and holding times an any given temperature, as desired. Temperature, pressure, and time-dependent changes thereof are generally process optimization parameters that will depend on the bulk source material, substrate material, and/or type or structure of nanomaterial formed. The growth surface of the substrate can be at the same temperature as the bulk solid phase or at a lower or higher temperature during growth (i.e., deposition) of the nanomaterial. For example, the vapor phase transport from the bulk source material to/from the growth surface can be in the direction of a positive or negative temperature gradient. Molecules and/or atoms from the bulk source material, after entering a vapor phase, can then collect, condense, or be deposited upon the growth surface of the substrate as a layer having single atomic thickness, a nanolayer, a nanofilm, or as patches or separated 2D crystals of the nanomaterial.

Metal chalcogenides can be categorized into transition metal and main group metal chalcogenides (MMCs). The transition metal chalcogenides can include two subsets: the transition metal dichalcogenides with the form of MX₂ (e.g., M=Mo, Was semiconductor; V, Nb, Ta as metal) and the transition metal trichalcogenides of the form of MX₃ (e.g., M=Ti, Zr, Hf), where X represents a chalcogen (e.g., S, Se, Te). Besides transition metal chalcogenides, MMCs, with the form of MX, MX₂ and M₂X₃ (e.g., M=Ga, In, Ge, Sn; X═S, Se, Te), also can be used for multiple phase nanomaterials including 2D nanomaterials.

The 2D materials formed on the substrate can be characterized, for example, using an optical microscope, atomic force microscope (AFM), Raman spectroscopy, X-ray diffraction, or photoluminescence, which can be used to demonstrate structure, chemical composition, purity, homogeneity, distribution of dopants, presence or absence of defects, or other properties.

The methods described herein are capable of direct synthesis because a bulk source is directly converted into a 2D nanomaterial without chemical reaction or without changing the chemical nature of the bulk source material, only its physical state and form. Compared to CVD, the methods disclosed herein can be performed without gas flow. Alternatively, inert gas can flow through the heated environment at a rate of less than about 0.5 cc/minute, less than about 0.25 cc/minute, less than about 0.1 cc/min, or about 0.0 cc/min (i.e., flow rate below limit of detection or no flow).

The technology can be utilized for direct synthesis of any form of nanomaterials, which can include amorphous forms or crystalline or co-crystalline structures, one or more layers of nanomaterials. Two-dimensional transition metal dichalcogenides (2D-TMDs) are beyond-graphene layered materials and have become a new platform for studying the physics of 2D semiconductors. With atomically thin layers confined in a 2D plane, 2D-TMDs manifest remarkable properties including indirect-to-direct band gap switching (Schaibley, et al., 2016), emergent photo-luminescence (Splendiani, et al., 2010), strong photovoltaic response (Ugeda, et al., 2014), anomalous lattice vibrations (Lee, et al., 2010), strong light-matter interactions at hetero-junctions (Wang, et al., 2020), valley-selective circular dichroism (Berghäuser, et al., 2018), excitonic dark states (Riche, et al., 2020), control of valley polarization using optical helicity (Mak, et al., 2012), and field-induced transport with a current ON-OFF ratio exceeding 10 (Mak, et al., 2012; Kumar, et al., 2020) that give 2D-TMDs immense potential for transistors, photodetectors, sensors, and many other applications (Hejazi, et al., 2019; Hejazi, et al., 2020; Mennel, et al., 2020).

2D molybdenum disulfide (2D-MoS₂) exhibits promising prospects as a low-cost, high sensitivity, and flexible next-generation semiconductor for optoelectronic, nano-electronic, photovoltaic, and valleytronic applications. Unlike graphene, which does not manifest a band gap, 2D-MoS₂ has a layer thickness-dependent band gap, which is indirect in the bilayer and above but becomes direct in the monolayer limit (Berg, et al., 2017). It has also been shown that it is possible to obtain the valley polarization of excitons using circularly polarized light excitations (Li, et al., 2018). Moreover, the sheet resistance of 2D-MoS₂ can be easily controlled either by applying a gate voltage, incident light, or injecting concentrations of dopants (Vandalon, et al., 2020). Further, 2D-MoS₂ is a strongly interacting system even in the presence of relatively high carrier densities (Wigner, 1934). These properties make 2D-MoS₂ a highly tunable and prime material for a wide range of applications such as photoemitters, photo-transistors, and photodetectors.

Excited-state dynamics in monolayer TMDs is sensitive to their quality, and their relaxation pathways are affected both by intrinsic (e.g., e-e, e-phonon interactions) and extrinsic (e.g. defect, temperature, etc.) factors. Hence, investigating photo-excited processes helps to compare the quality of 2D materials. The quasiparticle band gap (E_{g} ˜2.4 eV in monolayer MoS₂) (Hill, et al., 2016) characterizes single-particle (or quasiparticle) excitations and is defined by the sum of the energies needed to separately inject an electron and a hole into monolayer TMD (Brem, et al., 2018). The optical band gap (Eₒₚₜ ˜1.85 eV in monolayer MoS₂) describes the energy required to create an exciton in its ground state, a correlated two-particle electron-hole pair, via optical absorption (Park, et al., 2018). The difference in these energies (E_{g}−Eₒₚₜ) directly yields the exciton binding energy (E_{b}) (Kamban & Pedersen, 2020), which is about 20 times that of kT ˜25 meV at room temperature for monolayer MoS₂; hence, excitons are tightly bound in 2D materials (Park, et al., 2018).

In TMDs, enhanced Coulomb interactions due to low-dimensional effects are expected to increase the quasiparticle band gap as well as causing electron-hole pairs to form more strongly bound excitons (Cheiwchanchamnangij & Lambrecht, 2012). Photoluminescence (PL) measurements in charge-neutral 2D-MoS₂ show two excitonic peaks, associated with A-excitons and B excitons, each originating from one branch of the spin-orbit-split valence bands near the K-points of its first Brillouin zone (Hao, et al., 2016). Typically, substrate-induced injection of electrons leads to n-type doping of monolayer MoS₂ and results in the formation of stable trions, A⁻, with a slightly lower peak position (Heo, et al., 2018). The sharpness of the PL line widths associated with each of these excitonic peaks, i.e., the full width at half-maximum (FWHM) of excitonic/trionic peaks, is accepted as a nonperturbative measure of the quality of the 2D semiconductor (Xu, et al., 2019; McCreary, et al., 2016), since the line width in energy scale is inversely proportional to the lifetime of the excitation, i.e., how long it takes for exciton and/or trion to recombine (Hao, et al., 2016; Lin, et al., 2014). The line width is also an indicator of homogeneity/inhomogeneity of the material, i.e., whether it is a single crystal and shows uniform electronic/optoelectronic responses (Mak, et al., 2013). In an ideal situation where the material is homogeneous, and all transitions are direct, the line shape is expected to be narrow and obey a Lorentzian distribution (Toyozawa, 1962); as inhomogeneity and lattice vibrations, i.e., phonons, increase, there are additional contributions from indirect transitions as well, and the line shape starts to become broader and follow a Gaussian pattern (Toyozawa, 1962; Moody, et al., 2015). However, it is worth mentioning that the crystal quality-dependent change in the line shape is different from the temperature-dependent line width change.

At low temperatures, the PL is expected to be narrow, and by approaching the absolute zero kelvin, the PL line shape theoretically should approach the Dirac delta function (Christopher, et al., 2017). At room temperature, line width widening is also an effect of the temperature rising above absolute zero, which according to Fermi-Dirac distribution results in the change in Fermi function and, in turn, causes the increase in the line width of the exciton (Mouri, et al., 2013; Hawrylak, 1991). Thermal effects such as exciton-phonon coupling and density of states, also doping concentrations, can change the overall line shape of the PL, not merely the line width (Moody, et al., 2015; Christopher, et al., 2017). Although there are multiple factors affecting the PL line shape and line width, as long as the thermal effects, doping, and other factors are assumed to be the same, the only remaining factor that affects the line width is how well the 2D sample is synthesized, or, in other words, how disordered the crystal is. For this reason, the line width is a good measure of the quality of the 2D-MoS₂.

It is noted that it is common to use mobility as a measure of 2D material quality (Zhang, et al., 2018). While mobility is clearly an important parameter for quantifying the quality of 2D material, its measurement requires subjecting the sample to lithographic steps, which introduces unavoidable chemical contamination (Dan, et al., 2009), possible contact-resistance limitations (Urban, et al., 2020), and accurate estimations of sample geometry. In comparison, optical measures such as PL and Raman can be performed on as-grown crystals without any modifications, and hence this is a better measure of the quality of the pristine samples (Ajayi, et al., 2017; Srinivas, et al., 1992).

Obtaining high-quality 2D-TMDs that represent suitable properties both for enabling the demonstration of sensitive quantum phenomena, as well as for various applications, especially for high-performance optoelectronics, has so far been limited by the synthesis techniques (You, et al., 2018). There are new techniques such as pulsed laser deposition of 2D materials (Siegel, et al., 2015). These techniques, though promising for large-scale industrial applications, have certain production difficulties and do not possess the high-crystalline quality required for scientific research. It is believed that the highest-quality 2D samples, characterized by their narrow photoluminescence (PL) line width, can only be obtained by the top-down technique, mechanical exfoliation (ME) of the atomic layers of TMDs from their bulk crystals (Briggs, et al., 2019). Field-effect transistors (FETs) made from postprocessed ME samples have high ON-OFF switching ratios, high field-effect mobilities, and are sensitive to certain ranges of the visible spectrum (Wu, et al., 2013). However, there are significant challenges associated with ME in their inefficiency and difficulty of large-scale production, small lateral sample sizes, and spatial nonuniformities. Moreover, in order for any 2D samples to exhibit their high-quality properties, the 2D samples must be made extremely flat, which is only possible by capping them with boron-nitride (h-BN) (Auwärter, et al., 2019). The best-known 2D-TMDs are h-BN-capped ME samples, so the capping step adds to the complications of obtaining high-quality flat 2D samples. Hence, even though the ME technique for obtaining high-quality 2D samples is attractive, its poor yield (Yuan, et al., 2016), uncontrollable and irregular sample homogeneity, and not being scalable make this technique unsuitable for almost any practical applications (An, et al., 2018). Chemical vapor deposition (CVD), on the other hand, is a scalable technique, where, unlike ME, the large-scale single crystals of 2D-TMDs with uniform layer thicknesses over lateral sizes reaching hundreds of micrometers can be produced (Bilgin, et al., 2015). In CVD, TMDs are typically grown in a bottom-up approach, using MoO₃ and X (e.g., X═S, Se, W) as the precursors, and the samples are synthesized through a multistep chemical reaction of one or more precursors, usually in an inert atmosphere, where there is a flow of one or more carrier gases, and detailed control of temperature, pressure, flow rate, precursors-substrate distance, precursor-precursor distance, the temperature at each precursor location as well as at substrate location, for example, are crucial for high-quality homogeneous growth. CVD-produced 2D-TMDs are regarded as the high-potential candidates for practical industry-level integration with current complementary metal-oxide-semiconductor (CMOS) platforms (Shaygan, et al., 2017) but are still known to be of poor optoelectronic quality and poor yield, which has its root in the probabilistic nature of its two-step chemical deposition process (Zhang, et al., 2019). Previously, vapor-phase chalcogenization (VPC) was used, which is a one-step chemical reaction process that results in optoelectronic-grade 2D-TMDs (Bilgin, et al., 2015). In this method, the direct chemical conversion of MoO₂ to MoS₂ or MoSe₂ results in more complete crystalline conversion into the 2D-TMD samples, even without post-treatment, and hence were comparable to the ME samples, making VPC a more suitable technique for practical applications.

Wu et al. showed that it is possible to grow 2D-MoS₂ via vapor-phase transport, by flowing argon gas over heated bulk MoS₂ powder and allowing them to condense downstream on insulating substrates such as SiO₂ and sapphire, where the crystallographic quality was indirectly established by demonstrating valley polarization (Wu, et al., 2013). However, the direct comparison of these 2D crystals with those produced by other methods was not established. Moreover, this method still involves space-occupying components such as quartz tubes, furnaces, flow controllers, gas tanks, and associated flow lines and valves. Additionally, this technique also requires a detailed control of precursor amounts, and their distances from each other as well as from substrate. As it is well known, the presence of so many variables multiply the uncertainty for obtaining high-quality, reproducible samples. In other words, a simple fabrication technique without the need for multiple control parameters is far more attractive for advancing the science and applications of 2D materials. The present technology provides a non-complicated technique for synthesizing 2D materials, the flow-less direct growth (DG) of 2D-MoS₂ by heating commercially purchased bulk MoS₂ powder from a source onto proximally placed substrates, kept in an argon or inert atmosphere. The chemical-reaction-free transformation from bulk to vapor to 2D morphology suggests that the formation of mono and few layers is thermodynamically the most preferred morphology, and the absence of any oxygen and carrier-gas flow, as well as the physical proximity of the substrate, substantially eliminates the possibility of oxidation during crystal growth.

With thicknesses less than 1 nm, the 2D-MoS₂ samples fabricated by the presently presented technology possess some of the narrowest room-temperature excitonic line widths reported in literature to date, with the best A-exciton line width values as low as ˜36 meV. This is much lower compared to bare ME samples and comparable to those of h-BN-capped ME samples which are known to have the narrowest achievable line widths. The average A-exciton line width from samples produced by the methods herein is ˜40 meV with a standard deviation of 2.94 meV (i.e., <10% standard deviation in quality over several synthesis runs), which reflects extreme homogeneity for any “grown” 2D materials. The methods herein overcome the persisting complications such as the need for multiple precursors and carrier gases and hence pave the way for on-demand miniaturization of 2D-TMD synthesis. Unlike past attempts, the present technology requires no substrate pretreatment, and no sample posttreatment, such as capping or in situ annealing, is required in this technique to achieve samples with high qualities comparable to postprocessed ME samples. The directly grown samples by the presently disclosed DG technique manifest high optical responses, which is evident in their strong PL and feature-rich Raman spectra. It should be mentioned that defects often result in higher PL intensities (Wu, et al., 2018), as it is the case in the results presented during these studies. The higher intensity PL leads to higher background noise, which results in covering the weak higher-order Raman modes. Furthermore, in high-quality 2D samples, the Raman vibrational modes are well-defined, but as the density of defects increases, the vibrational modes start to overlap, which results in broadening the Raman peaks and suppressing the weak Raman modes. Considering these factors, the feature-rich Raman spectrum is a nondestructive measure of the quality of the 2D materials. The results of this research suggest that at least for TMDs, synthesized monolayers can be comparable if not better than mechanically exfoliated samples.

Where the growth substrate is not in contact with the source (e.g., MoS₂ powder), uniform, triangular single-crystal 2D-MoS₂ grows, as expected from the hexagonal lattice structure of MoS₂. However, at the same growth runs, at places where the substrate touches the source powder, the MoS₂ nucleation sites create spatial constraints on the formation of the crystals, where the samples are forced to “wrinkle” and form layers that appear in circular symmetries around the nucleation sites where the substrate has been in contact with the source. This phenomenon enables the methods herein to control the wrinkle-induced defects, especially wrinkles, in 2D materials, which is gaining attention as an attractive method for inducing novel phenomena and applications (Chen, et al., 2019; Tan, et al., 2020). More details of the synthesis, characterizations, and analyses of the quality of samples obtained in comparison to those from a variety of existing synthesis techniques are provided.

In FIG. 1B is depicted a flow-less direct growth technique, where a silicon wafer substrate 50 with a 300 nm thick silicon dioxide (Si/SiO₂) coating 55 is placed with coating facing down to MoS₂ powder 60 disposed on a Si/SiO₂ chip as the source 61, and together are placed inside a small quartz tube 65. The air is pumped out, the tube is back-filled with an inert gas, argon (Ar) in this case, and is sealed. However, the excess pressure is allowed to release through the valve 70 at high temperature, and the growth pressure is kept around 800 Torr, a bit above the atmospheric pressure, to prevent the air reentering the tube, but there is no carrier-gas flow. Since the as-purchased MoS₂ powder has large grains, the large powder grains are broke into smaller particles by ultrasonication in isopropyl alcohol (IPA) and the resulting suspension is uniformly drop-casted onto one Si/SiO₂ chip 61 as the source. At the right of FIG. 1B, the A-exciton linewidth of 2D-MoS₂ made by the direct growth method is directly compared with that of mechanically exfoliated (ME) and hBN-Capped 2D-MoS₂, showing the surprisingly small linewidths of the 2D-MoS₂ grown by direct growth. In particular, the A-exciton data shows small linewidths of 2D-MoS₂ grown by direct growth and without need for capping.

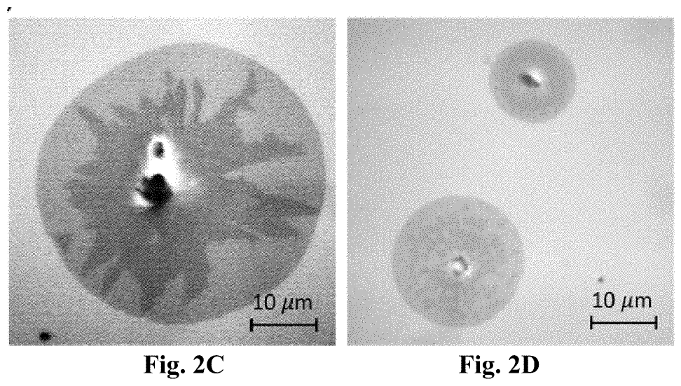

In FIG. 1C is shown examples of growth conditions that enable controlled growth of flat or wrinkled 2D-MoS₂. Flat samples (depicted at top left), i.e., triangular samples, are obtained when there is enough distance between the powder and substrate such that the powder does not physically contact the substrate, and vapor transport is the only method of growth (indicated by vertical arrows 80 at left of FIG. 1C); however, as the schematics for the wrinkled samples illustrate, wrinkled samples can controllably grow around a central physical seed, i.e., where the powder comes into contact with the source (indicated by angled arrows 85 at right of FIG. 1C). In this situation, 2D materials have to conform to the wrinkle enforced by the physical seed at a point of contact on the substrate; thus, samples start to grow in circular patterns, the phenomenon that wrinkles and even fractures the 2D samples. This phenomenon is illustrated by the Strained Samples depicted at the top right of FIG. 1C. These findings are exciting in the study of deformed 2D-TMD crystals and applications that require defected 2D-TMDs. FIG. 2A and FIG. 2B show typical triangular samples formed when the bulk source material does not physically contact the substrate. FIG. 2C and FIG. 2D show typical circular (wrinkled) samples at the same growth run (as FIG. 2A and FIG. 2B), where the layers of 2D-MoS₂ are wrinkled around the central physical seed (where the bulk source material does physically contact the substrate). Triangular second-layer crystals are also grown on the top of the circular regions in FIG. 2C and FIG. 2D.

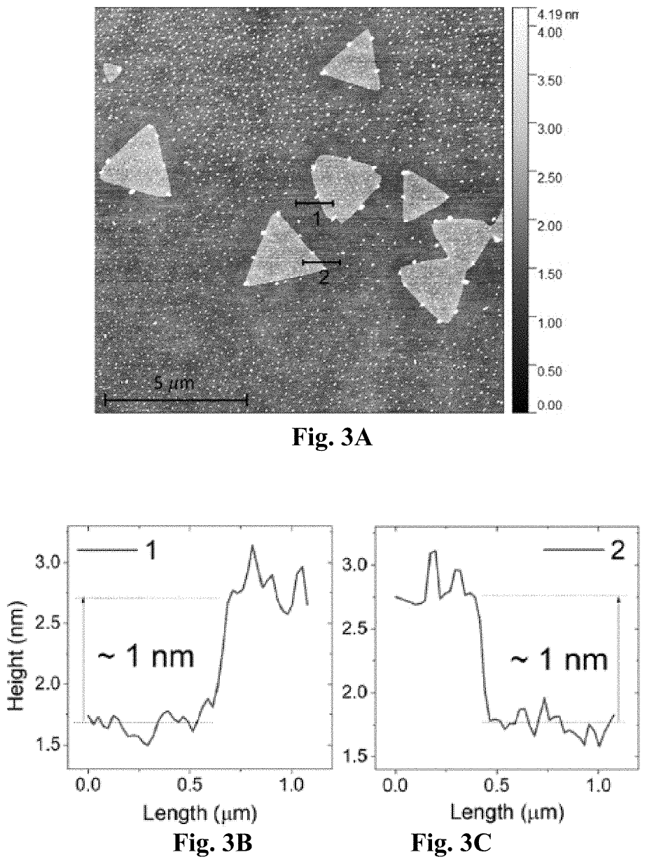

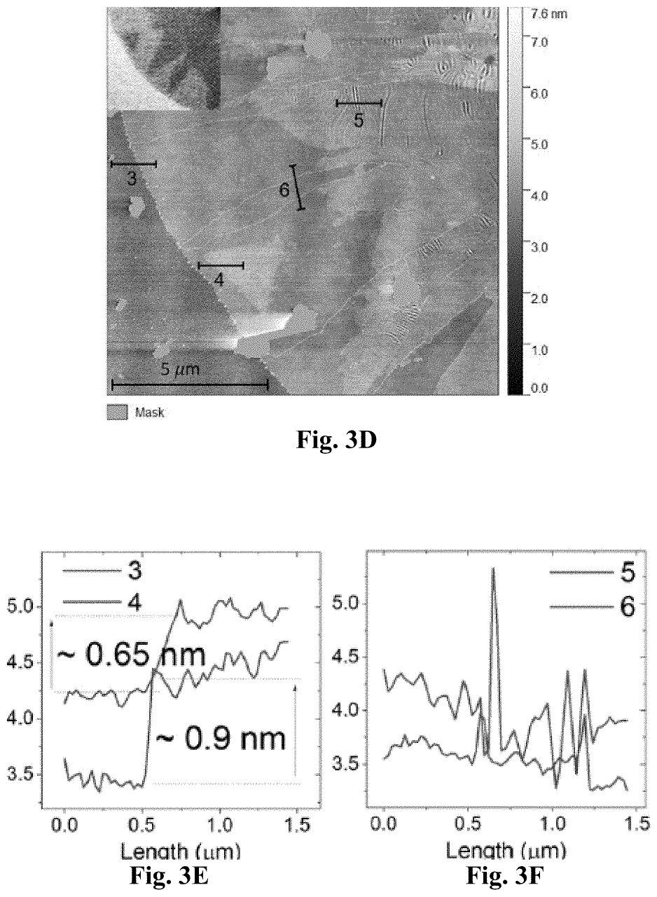

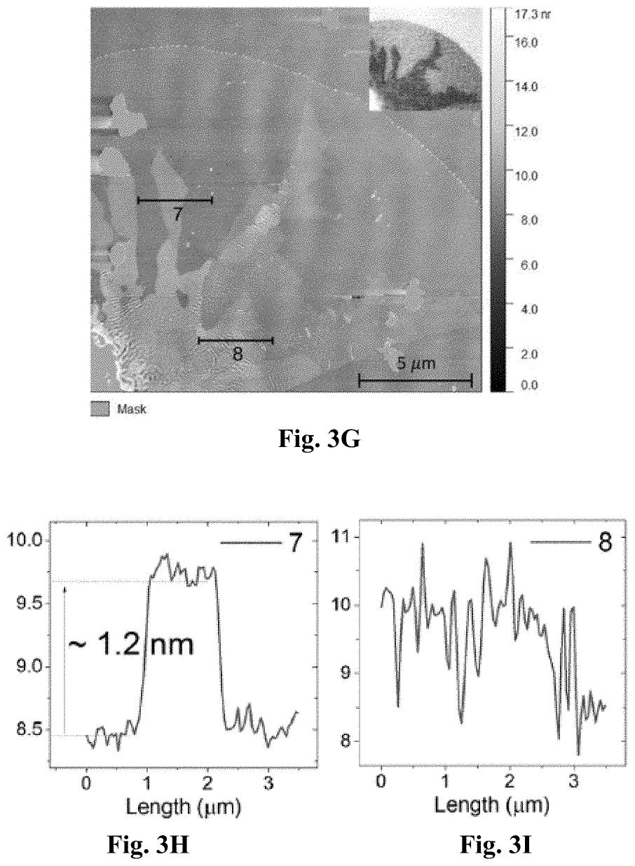

A more detailed study of the surface topology of these directly grown samples was obtained by atomic force microscopy (AFM) images. Example AFM results are shown in FIGS. 3A-31, wherein there are three AFM images and two cross-sectional line profile plots for each AFM image. In FIG. 3A, the scale bar at lower left depicts 5 μm. In FIG. 3A, typical triangular samples (2D samples) can be seen, with line 1 and line 2 depicting where two cross-sectional line profiles are plotted in FIG. 3B (line 1) and in FIG. 3C (line 2), estimating the step height (Z Axis) of the edge of 2D-MoS₂ on Si/SiO₂ to be about 1 nm. The average size (in the X/Y Axes) of monolayer triangular samples grown by the DG method is about 5 μm. In FIG. 3A, small domains (white dots or areas) of 2D-MoS₂ can also be seen, which are scattered around the bigger triangles; these white dots are the initial deposition regions, where the materials have started to grow. These dots are taller than the flat regions and make the deposition more favorable around the dots in the sublimation/resublimation competition.

FIG. 3D shows an AFM image from one portion of a wrinkled circular sample, where the stacked layers can be clearly seen, as well as wrinkles on the sample. This figure's inset (top left) shows the optical image of the sample's location from where the AFM image is acquired (compare to the image in FIG. 2C). In the AFM image of FIG. 3D, lines 3, 4, 5, and 6 indicate where step heights are measured in FIGS. 3E-3F. As can be seen in FIG. 3E, the step height of the edge of the circular sample is about 0.9 nm (line 3, FIG. 3E), almost the same as the triangular sample (e.g., lines 1 and 2, FIG. 3B and FIG. 3C), but a triangular crystal (line 4, FIG. 3D and FIG. 3E) is also seen appearing on top of the circular part, which has a step height of about 0.65 nm (line 4, FIG. 3E). FIG. 3F reveals the aforementioned wrinkles (line 5, line 6, FIG. 3D) on the wrinkled samples; towards the center of the wrinkled sample, the wrinkles become more prominent, which is expected since it is approaching the center of constraining geometry. The same pattern can be seen in the next three figures (FIG. 3G, FIG. 3H, FIG. 3I) acquired from a different part of the wrinkled sample.

To eliminate the possibility that these circular samples grow from possible defect sites on the substrate (as against contact-induced seeding), in repeated studies it is noted that these structures are never found to grow in “noncontact”, i.e., either when the substrate was physically separated from the source powder or during VPC synthesis. Additionally, each circular patch is characterized by a tall hillock at its center, providing evidence that the center was directly in contact with the MoS₂ bulk powder at the time of growth. These central hillocks are filtered in the AFM images, so the thinner growth areas can be captured in the AFM image. It is noted that in some cases, microns-scale MoS₂ particles may be electrostatically transferred from the source to the substrate during growth due to the proximity of the substrate from the source-powder surface, thus forming the seed for these circular samples. Growth from such a site can be expected to be similar to that of contact-induced seeding; the resulting growth mechanism can be expected to be similarly wrinkled.

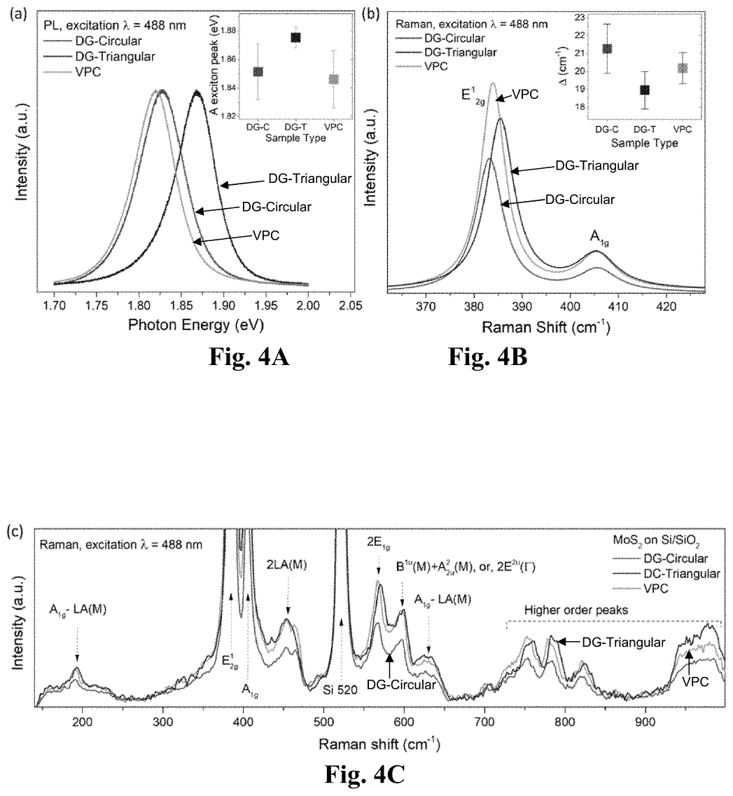

To study the optical properties, exciton/trion line width, and vibrational modes of these samples, the 2D-MoS₂ samples are excited by a 488 nm laser. In general the highest intensity values of PL are obtained from the exterior parts of the circular samples, which mostly wrinkled monolayer regions susceptible to band gap modulation that is known to enhance PL (Dhakal, et al., 2017). The normalized PL versus photon energies of three types of samples are given in FIG. 4A, taken from a typical directly grown, DG-triangular sample, a typical directly grown DG-circular wrinkled sample, and a typical VPC-grown sample for comparison.

Each obtained PL spectrum is Lorentz-curve-fitted to obtain the relative positions and contributions of excitons and trions. The inset of FIG. 4A shows the average values of A-exciton peak positions over all of the samples of the same type and their standard deviations (11 DG-triangular, 11 DG-circular, and 15 VPC samples), revealing two interesting observations. First, the A-exciton peak of directly grown triangular samples manifests higher peak energies on average, with very little deviation-suggesting the high uniformity of sample quality for this type of samples.

In comparison, the A-exciton peak for both DG-circular and VPC-grown samples has lower peak energy positions and wider spreads (larger standard deviations). While spread-out values are expected in the wrinkled samples due to the random nature of the wrinkles in these samples, the much lower spread in the DG-triangular samples compared to VPC-grown samples is suggesting that DG-triangular architectures are far more uniform than the latter as well. The direct growth approach allows for the first time to compare the A-exciton position between wrinkled and flat samples grown in the same run. It is found that wrinkles in the DG samples led to average red shifts of ˜30 meV in the A-exciton peak position. Second, the similarity of their peak positions and variations also suggests that VPC samples may have larger intrinsic wrinkle compared to the DG-triangular samples. The similarity between the DG-circular and VPC samples is also reflected in Raman peak positions. FIG. 4B shows the Raman spectrum versus wavenumber of the same three types of samples, with the signature E¹_{2g} and A_{1g} Raman modes for MoS₂ (Xia, 2018). These graphs were smoothed and normalized with respect to silicon peaks (from the substrate) that appear at 520 cm⁻¹. The inset of FIG. 4B shows the average Raman peak separations between A_{1g} and E¹_{2g} (i.e., Δ=ω[A_{1g}]−ω[E_{2g}¹])—the value of which is expected to be between ˜18 and 22 cm⁻¹ for monolayer MoS₂ (Bilgin, et al., 2015)—collected from all of the samples of the same type, and their standard deviations. In this case, it was found that Δ is smaller for the DG-triangular (DG-T) samples compared to the wrinkled (DG-C) or VPC samples—suggesting that increasing wrinkle within the crystal is at least partially responsible for the higher values of Δ, it is also possible to quantify the impact of wrinkle on the Raman peak positions. Wrinkle led to average red shifts of ˜2 cm⁻¹ in the E¹_{2g} Raman peak position in the DG samples. From these results, it appears that the DG-triangular samples have both higher crystallinity and lower intrinsic wrinkle compared to VPC-grown samples. Finally, FIG. 4C shows the as-collected Raman spectra that appear in FIG. 4B but significantly magnified to reveal prominent Raman-active modes in MoS₂. It had previously been established that optoelectronic-grade VPC-grown TMDs appear to reveal a significantly higher number of Raman peaks as compared to those from other methods (Bilgin, et al., 2015; Bilgin, et al., 2018). In this figure, DG-grown samples were found to reproduce every single one of those rich Raman modes of 2D-MoS₂ attributed to the various lattice vibrational modes of this material under optical excitation, see Bilgin et al. for comparison (Bilgin, et al., 2015). Taken together, the Raman spectral analysis also confirms the high-crystalline quality of DG-grown samples.

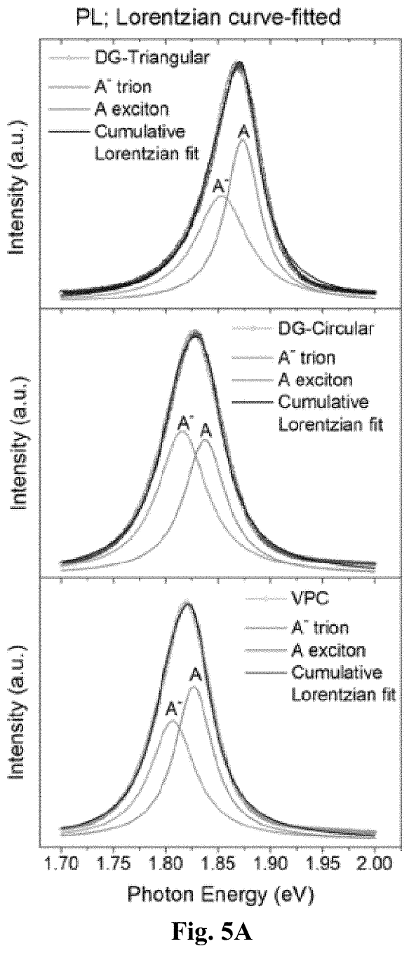

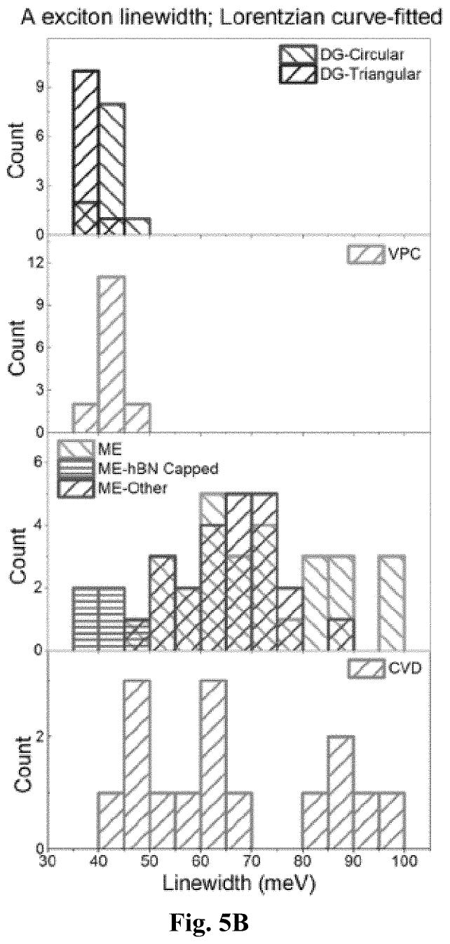

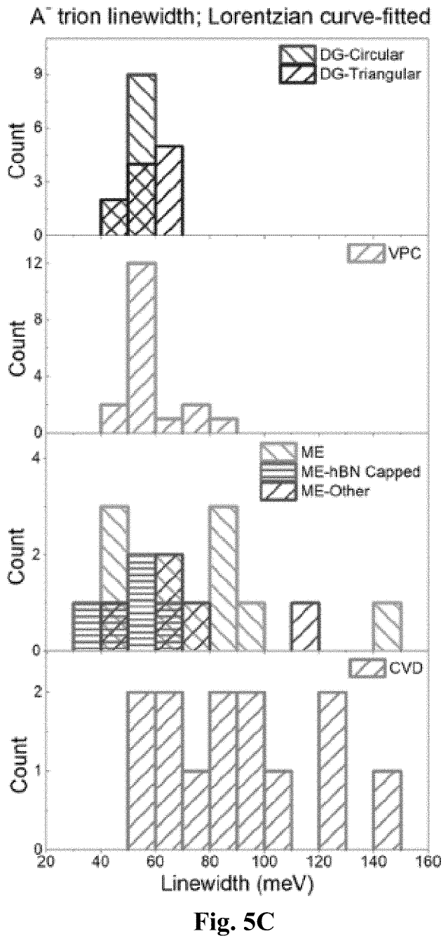

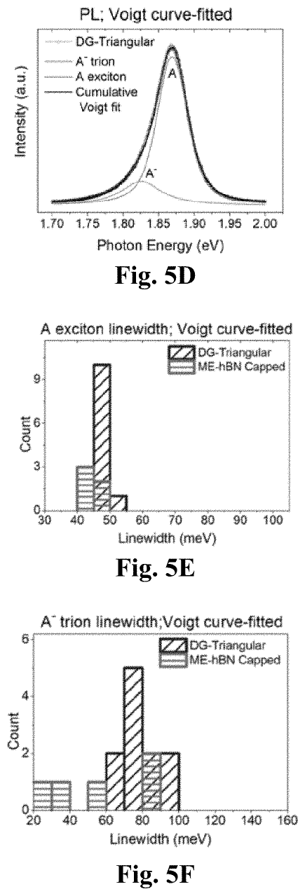

Then the line shape analysis of PL spectra was investigated, which can be considered to be one of the most stringent tests to evaluate the crystalline quality of TMDs. Lattice vibrations and lattice imperfections affect the line shape of the PL spectrum (Bulakh, et al., 2004; Mack, et al., 2017). When the coupling between the exciton and lattice vibrations or phonons is sufficiently weak, the line shape is expected to be Lorentzian, which is often used to curve-fit the exciton and trion in the literature (Toyozawa, 1962). For this reason, Lorentzian functions were used to fit A-exciton and A⁻-trion in the PL data. FIG. 5A shows typical curve-fits to these samples, where the excitons and trions are labeled. For comparison, also performed is an extensive analysis on the line width of 2D-MoS₂ samples fabricated on Si/SiO₂ by various other techniques reported in literature (see Lin, et al., 2014; Mak, et al., 2013; Christopher, et al., 2017; Bilgin, et al., 2015; Cadiz, et al., 2017; Sercombe, et al., 2013; Sun, et al., 2017; Pandey & Soni, 2019; Özküçük, et al., 2020; Zeng, et al., 2018; Nan, et al., 2014; Kaplan, et al., 2016; Xu, et al., 2018; and Gontijo, et al., 2019). Analyses are performed either using the published numerical data in articles or by digitizing the PL data from the published images within these articles. Curve-fitting is performed using Lorentzian functions in the same way as for samples obtained with the present technology. The histograms of A-exciton line widths of the 2D-MoS₂ samples fabricated by various techniques are shown in FIG. 5B, and the histograms of corresponding A⁻-trion line widths are shown in FIG. 5C. It was found that the median A-exciton line widths of DG-triangular, DG-circular, VPC-grown, untreated ME, and CVD-grown samples are 39.37, 41.44, 62.17, and 64.24 meV, respectively. Taking line width narrowness as a comparison metric, the remarkable result from FIG. 5B and FIG. 5C is found that the directly grown and VPC samples are among the best quality as-grown/fabricated samples. Further, with the median line width of h-BN-capped ME samples at 40.92 meV, similar to that of the directly grown triangular samples-suggesting that directly grown triangular samples are intrinsically superior in quality when compared to some of the best samples reported in literature. The DG methods disclosed herein enable superior quality without complicated techniques. The relatively more compact distribution of the line widths for DG and VPC technique-grown samples suggest that samples fabricated through these approaches are uniformly of higher quality, compared to many other techniques whose line width distributions are far more spread-out. As expected, CVD-grown samples also reveal the lowest quality and the somewhat random probability of getting relatively good samples.

A similar comparison of the A⁻-trion line widths reveals a similar picture, i.e., directly grown (DG) and VPC samples appear to have comparable line widths as ME (both h-BN-capped and uncapped) samples that are far superior to that of CVD-grown samples, and with much higher homogeneity of line width distributions.

Finally, a more stringent comparison between DG samples and ME samples is performed. The underlying mechanisms that govern the overall PL and, consequently, exciton/trion line shape is a debated subject (Ajayi, et al., 2017; Merritt, et al., 2014; Grundmann & Dietrich, 2009). As mentioned earlier, in an ideal situation, the PL is a sum of Lorentzian distributions. However, as lattice vibrations and defects start to perturb the exciton-phonon coupling, it adds a Gaussian component to the statistical distribution as well. Even though curve-fitting the PL to a set of Lorentzian functions is an accepted method by the majority of the TMD community, some researchers also use a combination of Lorentzian and Gaussian fitting functions (Okada, et al., 2018; Kaupmees, et al., 2019). This distribution does not have a closed-form solution and must be solved via numerical approaches, using the so-called “Voigt” function.

To perform the most stringent study of the DG samples and compare them with the best available other samples, i.e., mechanically exfoliated h-BN-capped samples, also a set of Voigt functions is fitted to the triangular samples grown by the DG method as well as the h-BN-capped ME samples. FIG. 5D shows a typical Voigt function fit to a PL spectrum obtained from DG-triangular samples, elucidating the high quality of this fit. The results of these fitting analyses are shown in FIG. 5E and FIG. 5F. It is found that even after using a Voigt fit, the line width qualities of the DG samples are well comparable to the h-BN-capped ME samples with 40-50 meV line width of A-exciton. For the A⁻-trion, although the best h-BN-capped ME samples appear to have lower line widths, the median values of the two types are comparable as well. Detailed, systematic analysis shows that noncontact samples (DG-triangular) of 2D-MoS₂ synthesized using the direct growth technique indeed results in high sample quality, with narrower room temperature A-exciton line widths compared to all other known (unprocessed) methods, and closely comparable to h-BN-encapsulated ME samples. Taken together with the simplicity of this approach, the present technology provides low-cost, high-quality, and easily accessible technology for 2D material synthesis.

The conventional methods of fabricating 2D-TMD devices all have limitations that make them challenging for practical use. While ME affords samples of high quality, it is not practical for fabricating 2D samples in large quantities. CVD synthesis provides scalability for practical application, but their material quality is still not electronic/optoelectronic grade. Based on PL and mobility measurements, the samples produced by VPC, a previously developed method, are superior in quality to CVD samples and the technique is scalable. However, the need for precise multiparameter control makes it often challenging to get reproducible samples in a typical scientific laboratory—and this process is not amenable for on-demand miniaturization. In the current work, it is shown that it is possible to obtain less than 1 nm thick micrometer-scale high-quality 2D-MoS₂ ideal for various optoelectronic applications comparable to state-of-the-art MoS₂ samples, using a low-cost, flow-less, facile, single-pot method that circumvents the need for any chemical reactions. The detailed PL and Raman analysis provided herein, especially the excitonic line width analysis, results establish that in contrast with the common misconception, high-quality optoelectronic-grade 2D-MoS₂ can be acquired by methods as simple as direct growth by heating of bulk sources without the need for flowing carrier gases. The A-exciton line width of a triangular 2D monolayer crystal grown by the direct method (DG method), without the need for capping or annealing, is about 35-40 meV, which is as sharp as the best attainable h-BN-capped ME samples; the A⁻ trion line width is also quite sharp for the DG samples. Furthermore, the comprehensive line width analysis also indicates that the direct method (DG method) has far more sample-to-sample homogeneity, compared to other methods, including ME.

It is quite remarkable that the DG approach, which can be the simplest conceivable one for growing 2D materials, results in samples that have much narrower line widths compared to those of as-exfoliated ME samples, and compared with ultra-flat h-BN-encapsulated ME samples, which have so far remained a hallmark of 2D-TMD quality. The technology also shows that by controlling the substrate's distance from the source, it is possible to obtain wrinkled samples that have spatial defects created by wrinkle-induced wrinkles on the grown 2D materials. As for the growth technique itself, on one hand, by overcoming the necessity of flowing a carrier-gas, mass-flow controllers, and multiple precursors makes the present DG method amenable for miniaturization since the confinement volume of Ar chamber can be suitably reduced to accommodate just the source and the substrate, and further allows the possibility of reducing the size of the furnace chamber, or use of nonstandard approaches such as solar heaters. On the other hand, this novel technique is also amenable for the scaled-up fabrication of 2D-TMDs on large-scale substrates. Other synthesis techniques have the limitations such as the need for a uniform carrier-gas flow rate on the surface of the substrate and a detailed control of distance/proportion of chemical precursors over a large area that makes fabricating 2D-TMDs on large-scale substrates almost impossible; this is where the direct growth technique has a novel advantage. Furthermore, alternative heating solutions, such as focused solar heating, are in principle compatible with the sealed tube method.

### EXAMPLES

### Example 1. Synthesis of 2D Nanomaterials

Commercially available MoS₂ powder was preprocessed by ultrasonication-assisted liquid phase exfoliation, to acquire smaller flakes, which increased the quality of the 2D samples. MoS₂ powder (99% Sigma-Aldrich) was first dispersed in isopropyl alcohol (IPA) (99.5% Alpha Aesar) with the ratio of 1:10 and kept for 1 hour; then, the dispersion was sonicated (UP100H Hielscher ultrasonic processor) at a setting of 30 kHz and 80% power for 8 hours, while the dispersion beaker was placed in room-temperature water to avoid overheating. When finished, the top half of the suspension, which contained 2D flakes of MoS₂ floating in the IPA, was collected and centrifuged for 2 minutes at 1000 rpm (Thermo Scientific centrifuge). The entire process was performed under ambient conditions (see Hejazi, et al., 2019 for more details on the LPE technique). Afterward, the top half of the suspension was collected and used as bulk source material for 2D-MoS₂ growth.

To perform direct growth of 2D-MoS₂, a piece of Si chip was used instead of a crucible (i.e., the piece of Si chip is referred to as a chip-crucible) and a few drops of the above-described MoS₂ suspension were placed on the Si chip. The IPA dried out in a few seconds, leaving small flakes of MoS₂ that could only be seen under a microscope (e.g., see Hejazi, et al., 2019 and Hejazi, et al., 2020). A 0.5 cm×0.5 cm chip was cut from a Si wafer with 300 nm thick SiO₂ coating (Addison Wafer) and used as a substrate. The chip surface was cleaned using a compressed air gun to remove particulates. To obtain an even cleaner substrate, The substrate was then placed facing down directly on the chip-crucible, making a sandwich. The sandwich in FIG. 1B shows MoS₂ powder 60, chip-crucible 61, Si substrate 50, and SiO₂ coating 55. The sandwich is also represented in FIG. 1A, with substrate 20, SiO₂ coating 25; chip-crucible 6, and MoS₂ (bulk source material) 5. Afterward, the sandwich was placed inside an alumina boat and the boat was slid inside a quartz tube (AdValue technology) to serve as sealable container, which was heated in an oven. To control the flat versus contact-mode fabrication, a narrow piece of Si wafer, as a wedge, was placed on one side, between the substrate and the chip-crucible. This allowed flat triangular growth in the areas closer to the wedge (no contact between SiO₂ growth surface), and contact-mode growth of circular samples more on the other side of the substrate, where the growth surface of the substrate came in direct contact with the chip-crucible. FIG. 1C illustrates that when the source powder is not in contact with the substrate (vertical arrows 80 at left), 2D-MoS₂ grew in the form of flat triangles, whereas, in the same growth run, where the powder came in contact with the substrate (angled arrows 85 at right), 2D-MoS₂ grew in the form of wrinkled circular patterns around the contact sites (i.e., nucleation sites).

Two slightly different approaches were then examined. In the first approach, the air was pumped out of the tube, which was back-filled with argon (99.99 Medical Technical Gases) several times, then filled with argon up to atmospheric pressure (−760 Torr), and the tube was sealed. The tube was heated from room temperature up to 650° C. at a rate of 100° C./min; then, it was heated to 750° C. at 5° C./min. Throughout the heating process, pressure built up inside the tube; to reduce the pressure, the seal (valve) was opened slowly and the extra argon allowed to leave the tube once every few minutes. The tube pressure was observed to make sure it did not drop below atmospheric pressure, to prevent re-entry of air into the tube, which could cause contamination and compromise growth. During growth, the pressure was about 770-800 Torr. In the second approach, after pumping the air out and filling the tube with argon, the tube was filled up to a fraction of atmospheric pressure, so when heating, even though the pressure builds up, it would not go much beyond the atmospheric pressure. The heating step was the same for both approaches.

In both approaches, after reaching 750° C., the tube was kept at 750° C. for 40 minutes. When finished, the furnace was opened and the tube was cooled down as fast as possible using an air fan. The tube was kept sealed until it cooled to room temperature. Afterward, the substrate was collected and used for optical measurements. The samples fabricated by the first approach were further characterized as described below.

### Example 2. Characterization of Synthesized 2D Nanomaterials

For optical measurements, the PL and Raman spectra were collected using a Modu-Laser Stellar-ReniShaw Raman spectroscopy tool equipped with a 150 mW, 488 nm laser. The laser light was focused on 2D-MoS₂ single crystals for about 1 minute in Raman-mapping and about 3 minutes in PL-mapping.

For atomic force microscopy (e.g., FIGS. 3A-31), the AFM images of the 2D-MoS₂ samples were collected using FastScan AFM instrument (Bruker Instruments, Billerica, Mass.) at the FastScan' ScanAsyst Mode using ScanAsyst cantilevers (Bruker Instruments).

For curve-fitting and digitizing the PL images, OriginPro commercial software was used to curve-fit the PL data. The PL data for the present samples were available, but for comparison with previously published literature, if their PL data was not publicly available, the same software was used to import images from the articles and digitized them to extract the PL data. When fitting a function, OriginPro was used to fit the superposition of either two Gaussians, two Lorentzians or two Voigt packages, one for A-exciton and one for A⁻ trion. In probability theory, a normal (or Gaussian or Gauss or Laplace-Gauss) distribution is a type of continuous probability distribution for a real-valued random variable. The general form of its probability density function is:

$$G ( x ; μ , σ ) = \frac{1}{\sqrt{2 π {σ}^{2}}} {e}^{- 1 / 2 {( \frac{x - μ}{σ} )}^{2}} \qquad ( Equation 1 )$$

The parameter μ is the mean or expectation of the distribution (and also its median and mode), while the parameter σ is its standard deviation. The variance of the distribution is σ².

Lorentz distribution, also known as the Cauchy distribution, Lorentzian function, Cauchy-Lorentz distribution, or Breit-Wigner distribution is also a continuous probability distribution, and the general form of its probability density function is:

$$L ( x ; {x}_{0} , γ ) = \frac{1}{π γ [ 1 + {( \frac{x - {x}_{0}}{γ} )}^{2} ]} \qquad ( Equation 2 )$$

where x₀ is the location parameter, specifying the location of the peak of the distribution, and γ is the scale parameter that specifies the half width at half-maximum (HWHM); alternatively, 2γ is full width at half-maximum (FWHM).

The Voigt profile (named after Woldemar Voigt) is a probability distribution given by a convolution of a Cauchy-Lorentz distribution and a Gaussian distribution. It is often used in analyzing data from spectroscopy or diffraction. Without loss of generality, one can consider only centered profiles, which peak at zero. The Voigt profile is then

V(x;σ,γ)=∫_{-∞}^{∞}G(x′;σ)L(x−x′;γ)dx (Equation 3)

where x is the shift from the line center, G(x; σ) is the centered Gaussian profile (μ=0), and L(x; γ) is the centered Lorentzian profile (x₀=0). As it could be seen, the Voigt function does not have a closed-form solution.

### REFERENCES

Schaibley, J. R.; Yu, H.; Clark, G.; Rivera, P.; Ross, J. S.; Seyler, K. L.; Yao, W.; Xu, X. Valleytronics in 2D Materials. Nat. Rev. Mater. 2016, 1, No. 16055.
Splendiani, A.; Sun, L.; Zhang, Y.; Li, T.; Kim, J.; Chim, C.-Y.; Galli, G.; Wang, F. Emerging Photoluminescence in Monolayer MoS2. Nano Lett. 2010, 10, 1271-1275.
Ugeda, M. M.; Bradley, A. J.; Shi, S.-F.; Felipe, H.; Zhang, Y.; Qiu, D. Y.; Ruan, W.; Mo, S.-K.; Hussain, Z.; Shen, Z.-X.; et al. Giant Bandgap Renormalization and Excitonic Effects in a Monolayer Transition Metal Dichalcogenide Semiconductor. Nat. Mater. 2014, 13, 1091-1095.
Lee, C.; Yan, H.; Brus, L. E.; Heinz, T. F.; Hone, J.; Ryu, S. Anomalous Lattice Vibrations of Single- and Few-Layer MoS₂. ACS Nano 2010, 4, 2695-2700.
Wang, Z.; Zhang, X.; Wu, D.; Guo, J.; Zhao, Z.; Shi, Z.; Tian, Y.; Huang, X.; Li, X. Construction of Mixed-Dimensional WS₂/Si Heterojunctions for High-Performance Infrared Photodetection and Imaging Applications. J. Mater. Chem. C 2020, 8, 6877-6882.
Berghäuser, G.; Bernal-Villamil, I.; Schmidt, R.; Schneider, R.; Niehues, I.; Erhart, P.; de Vasconcellos, S. M.; Bratschitsch, R.; Knorr, A.; Malic, E. Inverted Valley Polarization in Optically Excited Transition Metal Dichalcogenides. Nat. Commun. 2018, 9, No. 971.
Riche, F.; Bragan_{ç}a, H.; Qu, F.; Lopez-Richard, V.; Xie, S.; Dias, A.; Marques, G. E. Robust Room Temperature Emissions of Trion in Darkish WSe2 Monolayers: Effects of Dark Neutral and Charged Excitonic States. J. Phys. Condens. Matter 2020, 32, No. 365702.
Mak, K. F.; He, K.; Shan, J.; Heinz, T. F. Control of Valley Polarization in Monolayer MoS2 by Optical Helicity. Nat. Nano-technol. 2012, 7, 494-498.
Kumar, A.; Nazif, K. N.; Ramesh, P.; Saraswat, K. In Doped WS₂ Transistors with Large On-off Ratio and High on-Current, 2020 Device Research Conference (DRC); IEEE, 2020; pp 1-2.
Hejazi, D.; Liu, S.; Ostadabbas, S.; Kar, S. Transition Metal Dichalcogenide Thin Films for Precise Optical Wavelength Estimation Using Bayesian Inference. ACS Appl. Nano Mater. 2019, 2, 4075-4084.
Hejazi, D.; Liu, S.; Farnoosh, A.; Ostadabbas, S.; Kar, S. Development of Use-Specific High-Performance Cyber-Nanomaterial Optical Detectors by Effective Choice of Machine Learning Algorithms. Mach. Learn. Sci. Technol. 2020, 1, No. 025007.
Mennel, L.; Symonowicz, J.; Wachter, S.; Polyushkin, D. K.; Molina-Mendoza, A. J.; Mueller, T. Ultrafast Machine Vision with 2D Material Neural Network Image Sensors. Nature 2020, 579, 62-66.
Berg, M.; Keyshar, K.; Bilgin, I.; Liu, F.; Yamaguchi, H.; Vajtai, R.; Chan, C.; Gupta, G.; Kar, S.; Ajayan, P.; Ohta, T.; Mohite, A. D. Layer Dependence of the Electronic Band Alignment of Few-Layer MoS2 on SiO₂ Measured Using Photoemission Electron Microscopy. Phys. Rev. B 2017, 95, No. 235406.
Li, Z.; Liu, C.; Rong, X.; Luo, Y.; Cheng, H.; Zheng, L.; Lin, F.; Shen, B.; Gong, Y.; Zhang, S.; et al. Tailoring MoS2 Valley-Polarized Photoluminescence with Super Chiral Near-Field. Adv. Mater. 2018, 30, No. 1801908.
Vandalon, V.; Verheijen, M. A.; Kessels, W. M.; Bol, A. A. Atomic Layer Deposition of Al Doped MoS2: Synthesizing Ap-Type 2D Semiconductor with Tunable Carrier Density. ACS Appl. Nano Mater. 2020, 3, 10200-10208.
Wigner, E. On the Interaction of Electrons in Metals. Phys. Rev. 1934, 46, 1002.
Hill, H. M.; Rigosi, A. F.; Rim, K. T.; Flynn, G. W.; Heinz, T. F. Band Alignment in MoS2/WS2 Transition Metal Dichalcogenide Heterostructures Probed by Scanning Tunneling Microscopy and Spectroscopy. Nano Lett. 2016, 16, 4831-4837.
Brem, S.; Selig, M.; Berghaeuser, G.; Malic, E. Exciton Relaxation Cascade in Two-Dimensional Transition Metal Dichalco-genides. Sci. Rep. 2018, 8, No. 8238.
Park, S.; Mutz, N.; Schultz, T.; Blumstengel, S.; Han, A.; Aljarb, A.; Li, L.-J.; List-Kratochvil, E. J.; Amsalem, P.; Koch, N. Direct Determination of Monolayer MoS₂ and WSe₂ Exciton Binding Energies on Insulating and Metallic Substrates. 2D Mater. 2018, 5, No. 025003.
Kamban, H. C.; Pedersen, T. G. Interlayer Excitons in van Der Waals Heterostructures: Binding Energy, Stark Shift, and Field-Induced Dissociation. Sci. Rep. 2020, 10, No. 5537.
Cheiwchanchamnangij, T.; Lambrecht, W. R. Quasiparticle Band Structure Calculation of Monolayer, Bilayer, and Bulk MoS₂. Phys. Rev. B 2012, 85, No. 205302.
Hao, K.; Moody, G.; Wu, F.; Dass, C. K.; Xu, L.; Chen, C.-H.; Sun, L.; Li, M.-Y.; Li, L.-J.; MacDonald, A. H.; et al. Direct Measurement of Exciton Valley Coherence in Monolayer WSe2. Nat. Phys. 2016, 12, 677-682.
Heo, K.; Jo, S.-H.; Shim, J.; Kang, D.-H.; Kim, J.-H.; Park, J.-H. Stable and Reversible Triphenylphosphine-Based n-Type Doping Technique for Molybdenum Disulfide (MoS2). ACS Appl. Mater. Interfaces 2018, 10, 32765-32772.
Xu, L.; Zhao, L.; Wang, Y.; Zou, M.; Zhang, Q.; Cao, A. Analysis of Photoluminescence Behavior of High-Quality Single-Layer MoS2. Nano Res. 2019, 12, 1619-1624.
McCreary, A.; Berkdemir, A.; Wang, J.; Nguyen, M. A.; Elias, A. L.; Perea-López, N.; Fujisawa, K.; Kabius, B.; Carozo, V.; Cullen, D. A.; et al. Distinct Photoluminescence and Raman Spectroscopy Signatures for Identifying Highly Crystalline WS₂ Monolayers Produced by Different Growth Methods. J. Mater. Res. 2016, 31, 931-944.
Lin, Y.; Ling, X.; Yu, L.; Huang, S.; Hsu, A. L.; Lee, Y.-H.; Kong, J.; Dresselhaus, M. S.; Palacios, T. Dielectric Screening of Excitons and Trions in Single-Layer MoS₂. Nano Lett. 2014, 14, 5569-5576.
Mak, K. F.; He, K.; Lee, C.; Lee, G. H.; Hone, J.; Heinz, T. F.; Shan, J. Tightly Bound Trions in Monolayer MoS₂. Nat. Mater. 2013, 12, 207-211.
Toyozawa, Y. Further Contribution to the Theory of the Line-Shape of the Exciton Absorption Band. Prog. Theor. Phys. 1962, 27, 89-104.
Moody, G.; Dass, C. K.; Hao, K.; Chen, C.-H.; Li, L.-J.; Singh, A.; Tran, K.; Clark, G.; Xu, X.; Berghäuser, G.; et al. Intrinsic Homogeneous Linewidth and Broadening Mechanisms of Excitons in Monolayer Transition Metal Dichalcogenides. Nat. Commun. 2015, 6, No. 8315.
Christopher, J. W.; Goldberg, B. B.; Swan, A. K. Long Tailed Trions in Monolayer MoS2: Temperature Dependent Asymmetry and Resulting Red-Shift of Trion Photoluminescence Spectra. Sci. Rep. 2017, 7, No. 213116.
Mouri, S.; Miyauchi, Y.; Matsuda, K. Tunable Photoluminescence of Monolayer MoS2 via Chemical Doping. Nano Lett. 2013, 13, 5944-5948.
Hawrylak, P. Optical Properties of a Two-Dimensional Electron Gas: Evolution of Spectra from Excitons to Fermi-Edge Singularities. Phys. Rev. B 1991, 44, No. 3821.
Zhang, H.; Chhowalla, M.; Liu, Z. 2D Nanomaterials: Graphene and Transition Metal Dichalcogenides. Chem. Soc. Rev. 2018, 47, 3015-3017.
Dan, Y.; Lu, Y.; Kybert, N. J.; Luo, Z.; Johnson, A. C. Intrinsic Response of Graphene Vapor Sensors. Nano Lett. 2009, 9, 1472-1475.
Urban, F.; Lupina, G.; Grillo, A.; Martucciello, N.; et al. Di Bartolomeo, A. Contact Resistance and Mobility in Back-Gate Graphene Transistors. Nano Express 2020, 1, No. 010001.
Ajayi, O. A.; Ardelean, J. V.; Shepard, G. D.; Wang, J.; Antony, A.; Taniguchi, T.; Watanabe, K.; Heinz, T. F.; Strauf, S.; Zhu, X.; et al. Approaching the Intrinsic Photoluminescence Linewidth in Transition Metal Dichalcogenide Monolayers. 2D Mater. 2017, 4, No. 031011.
Srinivas, V.; Hryniewicz, J.; Chen, Y. J.; Wood, C. E. Intrinsic Linewidths and Radiative Lifetimes of Free Excitons in GaAs Quantum Wells. Phys. Rev. B 1992, 46, 10193.
You, J.; Hossain, M. D.; Luo, Z. Synthesis of 2D Transition Metal Dichalcogenides by Chemical Vapor Deposition with Controlled Layer Number and Morphology. Nano Convergence 2018, 5, No. 26.
Siegel, G.; Subbaiah, V.; Prestgard, Y.; Tiwari, M. C. A Growth of Centimeter-Scale Atomically Thin MoS2 Films by Pulsed Laser Deposition. APL Mater. 2015, 3, No. 056103.
Briggs, N.; Subramanian, S.; Lin, Z.; Li, X.; Zhang, X.; Zhang, K.; Xiao, K.; Geohegan, D.; Wallace, R.; Chen, L.-Q.; et al. A Roadmap for Electronic Grade 2D Materials. 2D Mater. 2019, 6, No. 022001.
Wu, C.-C.; Jariwala, D.; Sangwan, V. K.; Marks, T. J.; Hersam, M. C.; Lauhon, L. J. Elucidating the Photoresponse of Ultrathin MoS2 Field-Effect Transistors by Scanning Photocurrent Microscopy. J. Phys. Chem. Lett. 2013, 4, 2508-2513.
Auwärter, W. Hexagonal Boron Nitride Monolayers on Metal Supports: Versatile Templates for Atoms, Molecules and Nanostruc-tures. Surf. Sci. Rep. 2019, 74, 1-95.
Yuan, L.; Ge, J.; Peng, X.; Zhang, Q.; Wu, Z.; Jian, Y.; Xiong, X.; Yin, H.; Han, J. A Reliable Way of Mechanical Exfoliation of Large Scale Two Dimensional Materials with High Quality. AIP Adv. 2016, 6, No. 125201.
An, S.-J.; Kim, Y. H.; Lee, C.; Park, D. Y.; Jeong, M. S. Exfoliation of Transition Metal Dichalcogenides by a High-Power Femtosecond Laser. Sci. Rep. 2018, 8, No. 12957.
Bilgin, I.; Liu, F.; Vargas, A.; Winchester, A.; Man, M. K.; Upmanyu, M.; Dani, K. M.; Gupta, G.; Talapatra, S.; Mohite, A. D.; et al. Chemical Vapor Deposition Synthesized Atomically Thin Molybdenum Disulfide with Optoelectronic-Grade Crystalline Quality. ACS Nano 2015, 9, 8822-8832.
Shaygan, M.; Otto, M.; Sagade, A. A.; Chavarin, C. A.; Bacher, G.; Mertin, W.; Neumaier, D. Low Resistive Edge Contacts to CVD-Grown Graphene Using a CMOS Compatible Metal. Ann. Phys. 2017, 529, No. 1600410.
Zhang, Y.; Yao, Y.; Sendeku, M. G.; Yin, L.; Zhan, X.; Wang, F.; Wang, Z.; He, J. Recent Progress in CVD Growth of 2D Transition Metal Dichalcogenides and Related Heterostructures. Adv. Mater. 2019, 31, No. 1901694.
Wu, S.; Huang, C.; Aivazian, G.; Ross, J. S.; Cobden, D. H.; Xu, X. Vapor-Solid Growth of High Optical Quality MoS2 Monolayers with near-Unity Valley Polarization. ACS Nano 2013, 7, 2768-2772.
Wu, K.; Li, Z.; Tang, J.; Lv, X.; Wang, H.; Luo, R.; Liu, P.; Qian, L.; Zhang, S.; Yuan, S. Controllable Defects Implantation in MoS 2 Grown by Chemical Vapor Deposition for Photoluminescence Enhancement. Nano Res. 2018, 11, 4123-4132.
Chen, W.; Gui, X.; Yang, L.; Zhu, H.; Tang, Z. Wrinkling of Two-Dimensional Materials: Methods, Properties and Applications. Nanoscale Horiz. 2019, 4, 291-320.
Tan, Y.; Hu, B.; Song, J.; Chu, Z.; Wu, W. Bioinspired Multiscale Wrinkling Patterns on Curved Substrates: An Overview. Nano-Micro Lett. 2020, 12, No. 101.
Dhakal, K. P.; Roy, S.; Jang, H.; Chen, X.; Yun, W. S.; Kim, H.; Lee, J.; Kim, J.; Ahn, J.-H. Local Strain Induced Band Gap Modulation and Photoluminescence Enhancement of Multilayer Transition Metal Dichalcogenides. Chem. Mater. 2017, 29, 5124-5133.
Xia, M. A Review on Applications of Two-Dimensional Materials in Surface-Enhanced Raman Spectroscopy. Int. J. Spectrosc. 2018, 2018, 1-10.
Bilgin, I.; Raeliarijaona, A. S.; Lucking, M. C.; Hodge, S. C.; Mohite, A. D.; de Luna Bugallo, A.; Terrones, H.; Kar, S. Resonant Raman and Exciton Coupling in High-Quality Single Crystals of Atomically Thin Molybdenum Diselenide Grown by Vapor-Phase Chalcogenization. ACS Nano 2018, 12, 740-750.
Bulakh, B.; Khomenkova, L.; Kushnirenko, V.; Markevich, I. The Influence of Crystal Imperfections on the Shape of Exciton Emission Spectrum in ZnO Single Crystals. Eur. Phys. J.: Appl. Phys. 2004, 27, 305-307.
Mack, T. G.; Jethi, L.; Kambhampati, P. Temperature Dependence of Emission Line Widths from Semiconductor Nano-crystals Reveals Vibronic Contributions to Line Broadening Processes. J. Phys. Chem. C 2017, 121, 28537-28545.
Cadiz, F.; Courtade, E.; Robert, C.; Wang, G.; Shen, Y.; Cai, H.; Taniguchi, T.; Watanabe, K.; Carrere, H.; Lagarde, D.; et al. Excitonic Linewidth Approaching the Homogeneous Limit in MoS₂-Based van Der Waals Heterostructures. Phys. Rev. X2017, 7, No. 021026.
Sercombe, D.; Schwarz, S.; Del Pozo-Zamudio, O.; Liu, F.; Robinson, B.; Chekhovich, E.; Tartakovskii, I.; Kolosov, O.; Tartakovskii, A. Optical Investigation of the Natural Electron Doping in Thin MoS2 Films Deposited on Dielectric Substrates. Sci. Rep. 2013, 3, No. 3489.
Sun, L.; Zhang, X.; Liu, F.; Shen, Y.; Fan, X.; Zheng, S.; Thong, J. T.; Liu, Z.; Yang, S. A.; Yang, H. Y. Vacuum Level Dependent Photoluminescence in Chemical Vapor Deposition-Grown Monolayer MoS 2. Sci. Rep. 2017, 7, No. 16714.
Pandey, J.; Soni, A. Unraveling Biexciton and Excitonic Excited States from Defect Bound States in Monolayer MoS2. Appl. Surf. Sci. 2019, 463, 52-57.
Özküçük, G. U.; Odacι, C.; Şahin, E.; Ay, F.; Perkgöz, N. K. Glass-Assisted CVD Growth of Large-Area MoS2, WS2 and MoSe2 Monolayers on Si/SiO₂ Substrate. Mater. Sci. Semicond. Process. 2020, 105, No. 104679.
Zeng, Y.; Chen, W.; Tang, B.; Liao, J.; Lou, J.; Chen, Q. Synergetic Photoluminescence Enhancement of Monolayer MoS 2 via Surface Plasmon Resonance and Defect Repair. RSC Adv. 2018, 8, 23591-23598.
Nan, H.; Wang, Z.; Wang, W.; Liang, Z.; Lu, Y.; Chen, Q.; He, D.; Tan, P.; Miao, F.; Wang, X.; et al. Strong Photoluminescence Enhancement of MoS2 through Defect Engineering and Oxygen Bonding. ACS Nano 2014, 8, 5738-5745.
Kaplan, D.; Gong, Y.; Mills, K.; Swaminathan, V.; Ajayan, P.; Shirodkar, S.; Kaxiras, E. Excitation Intensity Dependence of Photoluminescence from Monolayers of MoS₂ and WS2/MoS2 Heterostructures. 2D Mater. 2016, 3, No. 015005.
Xu, W.; Kozawa, D.; Liu, Y.; Sheng, Y.; Wei, K.; Koman, V. B.; Wang, S.; Wang, X.; Jiang, T.; Strano, M. S.; et al. Determining the Optimized Interlayer Separation Distance in Vertical Stacked 2D WS2: HBN: MoS2 Heterostructures for Exciton Energy Transfer. Small 2018, 14, No. 1703727.
Gontijo, R. N.; Gadelha, A.; Silveira, O. J.; Carvalho, B. R.; Nunes, R. W.; Campos, L. C.; Pimenta, M. A.; Righi, A.; Fantini, C. Temperature Dependence of the Double-Resonance Raman Bands in Monolayer MoS2. J. Raman Spectrosc. 2019, 50, 1867-1874.
Merritt, T.; Meeker, M.; Magill, B. A.; Khodaparast, G. A.; McGill, S.; Tischler, J.; Choi, S.; Palmstrøm, C. Photoluminescence Lineshape and Dynamics of Localized Excitonic Transitions in InAsP Epitaxial Layers. J. Appl. Phys. 2014, 115, No. 193503.
Grundmann, M.; Dietrich, C. P. Lineshape Theory of Photoluminescence from Semiconductor Alloys. J. Appl. Phys. 2009, 106, No. 123521.
Okada, M.; Kutana, A.; Kureishi, Y.; Kobayashi, Y.; Saito, Y.; Saito, T.; Watanabe, K.; Taniguchi, T.; Gupta, S.; Miyata, Y.; et al. Direct and Indirect Interlayer Excitons in a van Der Waals Heterostructure of HBN/WS2/MoS2/HBN. ACS Nano 2018, 12, 2498-2505.
Kaupmees, R.; Komsa, H.-P.; Krustok, J. Photoluminescence Study of B-Trions in MoS2 Monolayers with High Density of Defects. Phys. Status Solidi B 2019, 256, No. 1800384.

1. A method for making a nanomaterial, the method comprising the steps of:
(a) providing a bulk source material, a substrate, an inert gas, an oven, and optionally a sealable container;
(b) placing the bulk source material and the substrate into the oven or the sealable container, wherein a growth surface of the substrate is disposed adjacent to the bulk source material;
(c) filling the oven or the sealable container with the inert gas and sealing the oven or sealable container to provide an inert atmosphere inside the oven or sealable container; and
(d) heating the bulk source material and the substrate in the inert atmosphere in the oven or in the sealable container placed in the oven, whereby a portion of the bulk source material forms a vapor and is deposited as the nanomaterial on the growth surface of the substrate.

2. (canceled)

3. The method of claim 1, wherein the growth surface does not contact the bulk source material during step (d), and wherein at least a portion of the nanomaterial deposited on the growth surface consists of one or more layers of a two-dimensional nanomaterial, each layer having a thickness of less than about 1 nm.

4. The method of claim 3, wherein the growth surface is separated from the bulk source material by a gap of from about 0.1 mm to about 3 cm.

5. The method of claim 1, wherein the growth surface contacts the bulk source material at one or more contact sites during step (d), and wherein at least a portion of the nanomaterial deposited on the growth surface consists of a two-dimensional nanomaterial at least partially surrounding the contact site and disposed in a wrinkled pattern on the growth surface.

6. The method of claim 1, wherein the bulk source material comprises M_{A}X_{B}, wherein M is a transition metal or a transition metal cation, X is a chalcogen, A=1 or 2, and B=1, 2, or 3.

7. The method of claim 6, wherein M is selected from the group consisting of Ti, Zr, Hf, V, Nb, Ta, Mo, W, Tc, Re, Co, Ni, Rh, Ir, Rd, and Pt; wherein X is selected from the group consisting of S, Se, and Te; and wherein A=1 and B=2.

8. (canceled)

9. The method of claim 1, wherein the bulk source material comprises two or more different bulk source materials having different chemical compositions, and wherein the deposited nanomaterial is an alloy of the two or more different bulk source materials.

10. The method of claim 1, wherein the deposited nanomaterial is a two-dimensional nanomaterial comprising a material selected from the group consisting of GaS, GaSe, InS, InSe, HfS₂, HfSe₂, HfTe₂, MoS₂, MoSe₂, MoTe₂, NbS₂, NbSe₂, NbTe₂, NiS₂, NiSe₂, NiTe₂, PdS₂, PdSe₂, PdTe₂, PtS₂, PtSe₂, PtTe₂, ReS₂, ReSe₂, ReTe₂, TaS₂, TaSe₂, TaTe₂, TiS₂, TiSe₂, TiTe₂, WS₂, WSe₂, WTe₂, ZrS₂, ZrSe₂, and ZrTe₂.

11.-12. (canceled)

13. The method of claim 1, wherein the inert gas is sealed within the oven or container, without flow through the oven or container, during step (d).

14. The method of claim 1, wherein step (d) comprises raising the temperature in the oven to a first temperature followed by raising the temperature in the oven to a second temperature, higher than the first temperature, and then holding the oven temperature at the second temperature for a period of time sufficient to deposit the nanomaterial on the growth surface.

15.-16. (canceled)

17. The method of claim 14, wherein the first temperature is from about 500° C. to about 650° C. and the second temperature is from about 700° C. to about 900° C.

18. The method of claim 1, further comprising:
(e) cooling the substrate and the nanomaterial to ambient temperature.

19. The method of claim 18, wherein the substrate and the nanomaterial are kept in the inert atmosphere until cooled to the ambient temperature.

20. The method of claim 1, wherein the nanomaterial is deposited without chemical reaction of the bulk source material with another substance or the inert atmosphere.

21.-22. (canceled)

23. The method of claim 1, wherein the substrate is heated in step (d) to a different temperature than the bulk source material.

24. (canceled)

25. The method of claim 1, wherein the growth surface has a surface roughness less than about 1 nm RMS.

26. The method of claim 1, further comprising including a dopant material with the bulk source material or in the inert atmosphere.

27. The method of claim 1, further comprising doping the deposited nanomaterial by dry bulk contact or gas diffusion using a dopant material.

28. The method of claim 26, wherein the dopant material comprises Nb, Re, Fe, Re, V, N, Cs, Pb, I, CI, Au, NH₃, CH₃, benzyl viologen, oleylamine, triphenylphospine, polyethylenimine, pristine diketopyrrolopyrrole based polymer (PDPP3T), O₂, N₂, a rare earth element, a transition metal, a chalcogen, a semiconductor material, a magnetic material, or a combination thereof.

29. (canceled)

30. A nanomaterial made by the method of claim 1.

31.-32. (canceled)

33. A device comprising the nanomaterial of claim 30, wherein the device is selected from the group consisting of a substrate including the nanomaterial upon a surface of the substrate, a force detector, a direct band-gap device, an n-type device, a p-type device, an ambipolar carrier transport device, a field effect transistor, a direct write junction, a random access memory (RAM) device, an oscillator, a chemical and/or gas sensor, a zero-energy motion and/or zero-energy sensor device, an indirect-to-direct band gap switching device, a photo-luminescence device, a photovoltaic device, an accelerometer, an optical or electromagnetic filter, a plane polarizer, a circularly polarized filter, a pressure sensor, an energy storage device, and a conductor or a superconductor.
